(19) United States
(12) Patent Application Publication
(10) Pub. No.: US 2025/0254885 A1
(43) Pub. Date: Aug. 7, 2025

(54) SEMICONDUCTOR DEVICES HAVING FERROELECTRIC MEMORY CELLS AND METHODS OF FORMING THE SAME

(71) Applicant: TAIWAN SEMICONDUCTOR MANUFACTURING COMPANY, LTD., Hsinchu (TW)

(72) Inventors: Shih-Yu LIAO, Hsinchu (TW); Chung-Liang CHENG, Changhua (TW)

(21) Appl. No.: 18/435,128

(22) Filed: Feb. 7, 2024

(51) Int. Cl. H10B 51/30; H01L 23/528; H01L 29/78; H10B 51/10; H10B 51/40

(52) U.S. Cl. CPC H10B 51/30; H01L 23/5286; H10B 51/10; H10B 51/40; H10D 30/701

(57) ABSTRACT

Various embodiments of the present disclosure provide a semiconductor device structure. The semiconductor device structure includes a device layer having a first side and a second side opposing the first side, and a first interconnect structure disposed over the first side of the device layer. The first interconnect structure includes a first interconnect-level layer, a second interconnect-level layer disposed over the first interconnect-level layer, wherein the second interconnect-level layer comprises an array of vertical-type memory cell devices. The semiconductor device structure also includes a third interconnect-level layer disposed over the second interconnect-level layer.

### BACKGROUND

As the semiconductor industry has progressed into nanometer technology process nodes in pursuit of higher device density, higher performance, it is desirable to incorporate logic circuits having a variety of functions with non-volatile memory circuits within one chip. Since device feature sizes continue to decrease, there is a need in the art for a semiconductor device structure that could achieve the above-mentioned features with high integration density.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates an exemplary circuit diagram of a 1-transistor (1T) type FeRAM circuit in accordance with some embodiments.

FIG. 1B illustrates an array of memory devices employing a plurality of 1T type FeRAM circuits shown in FIG. 1A.

FIGS. 2A-2C are vertical cross-sectional views of an exemplary semiconductor device structure, in accordance with some embodiments of the present disclosure.

FIG. 3A is a vertical cross-sectional view of the exemplary semiconductor device structure taken along plane B-B of FIG. 3C.

FIG. 3B is a vertical cross-sectional view of the exemplary semiconductor device structure taken along plane A-A of FIG. 3C.

FIG. 3C is a horizontal cross-sectional view of an exemplary semiconductor device structure, in accordance with some embodiments of the present disclosure.

FIG. 4A is a vertical cross-sectional view of the exemplary semiconductor device structure taken along plane B-B of FIG. 4C.

FIG. 4B is a vertical cross-sectional view of the exemplary semiconductor device structure taken along plane A-A of FIG. 4C.

FIG. 4C is a horizontal cross-sectional view of an exemplary semiconductor device structure, in accordance with some embodiments of the present disclosure.

FIGS. 5-17 are vertical cross-sectional views of the exemplary semiconductor device structure during various stages of manufacturing, according to some embodiments of the present disclosure.

FIG. 18 illustrates a schematic diagram of a layout design, in accordance with the embodiment of FIG. 17.

FIG. 19 illustrates a schematic diagram of a layout design, in accordance with some embodiments of the present disclosure.

FIG. 20 illustrates a vertical cross-sectional view of an exemplary semiconductor device structure, in accordance with some embodiments.

FIGS. 21-28 are cross-sectional side views of various stages of manufacturing an exemplary semiconductor device structure, in accordance with some embodiments of the present disclosure.

FIG. 29 illustrates a cross-sectional side view of an exemplary semiconductor device structure, in accordance with some embodiments of the present disclosure.

FIG. 30 illustrates a cross-sectional side view of an exemplary semiconductor device structure, in accordance with some embodiments of the present disclosure.

FIG. 30-1 illustrates an enlarged view of a portion of the semiconductor device structure shown in FIG. 30, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments of the present disclosure are directed to semiconductor device structures having an array of memory cells disposed in a Back-End-Of-Line (BEOL) structure to improve device density and performance. Non-volatile memory technologies may include ferroelectric random-access memory (FeRAM), resistive random-access memory (RRAM or ReRAM), magneto-resistive random-access memory (MRAM), and phase-change memory (PCM), etc., for example. FeRAM devices are one promising candidate for next generation non-volatile memory technology due to its fast write/read speed, small size, low power consumption, and low manufacturing cost.

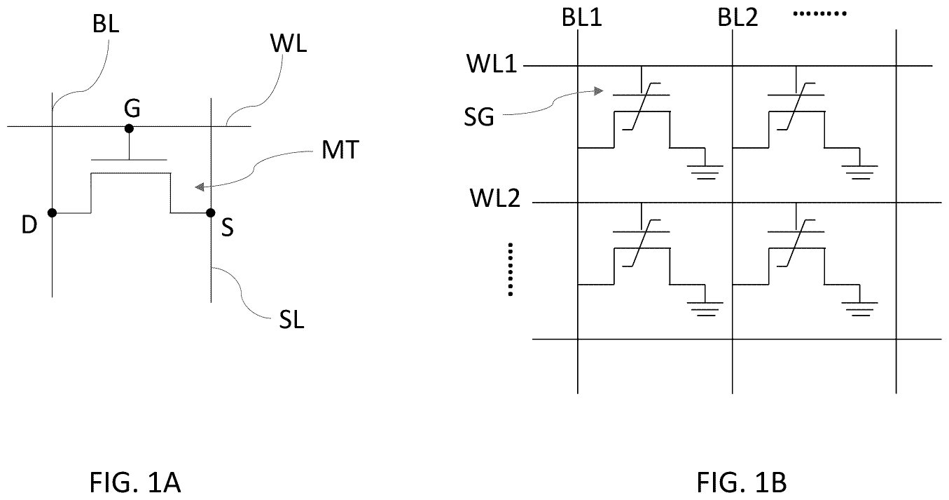

FIG. 1A illustrates an exemplary circuit diagram of a 1-transistor (1T) type FeRAM circuit in accordance with some embodiments. The 1T FeRAM circuit may function as a capacitor or a charge storage memory device to practice various embodiments of the present disclosure. As shown in FIG. 1A, an FeRAM circuit generally includes a word line (WL), a bit line (BL), a source line (SL), and a memory transistor (MT) having a gate (G) coupled to the word line, a drain (D) coupled to the bit line, and a source(S) coupled to the source line, which may be grounded. FIG. 1B illustrates an array of memory devices employing a plurality of 1T type FeRAM circuits shown in FIG. 1A. The plurality of FeRAM circuits within a row are operably coupled to word lines WL1, WL2, . . . , by way of a select gate (SG) and to control gate line. The plurality of FeRAM circuits within a column are operably coupled to bit lines BL1, BL2, . . . , and to source line. The gate may be controlled by a first voltage from the word line, the drain may be controlled by a second voltage from the bit line, and the source may be controlled by a third voltage from the source line. In some embodiments, the source is grounded. In some embodiments, the drain is grounded.

As will be discussed in more detail below, the FeRAM circuit can be configured as a vertical-type gate-all-around (GAA) structure having a channel region (vertically disposed between a top source/drain feature and a bottom source/drain feature) fully surrounded by a gate. A layer of ferroelectric material may be disposed between the gate and the channel region. The ferroelectric material can maintain electrical polarization in the absence of external electrical field. The electrical polarization in the ferroelectric material has a hysteresis effect, enabling encoding of a data bit as a polarization direction within the ferroelectric material. Polarization of the ferroelectric material is able to change the threshold voltage of the FeRAM circuit by detecting a change in the threshold voltage of the gate. For example, when an external electric field is applied across a dielectric, the dipoles tend to align themselves with the field direction, produced by small shifts in the positions of atoms and shifts in the distributions of electronic charge in the ferroelectric material. After the charge is removed, the dipoles retain their polarization state. In a 1T-type FeRAM, the remaining polarization state affects a threshold voltage Vt of the gate, and when a voltage is applied, a current value changes depending on the remaining polarization state, thereby storing/reading binary “0” and “1” data.

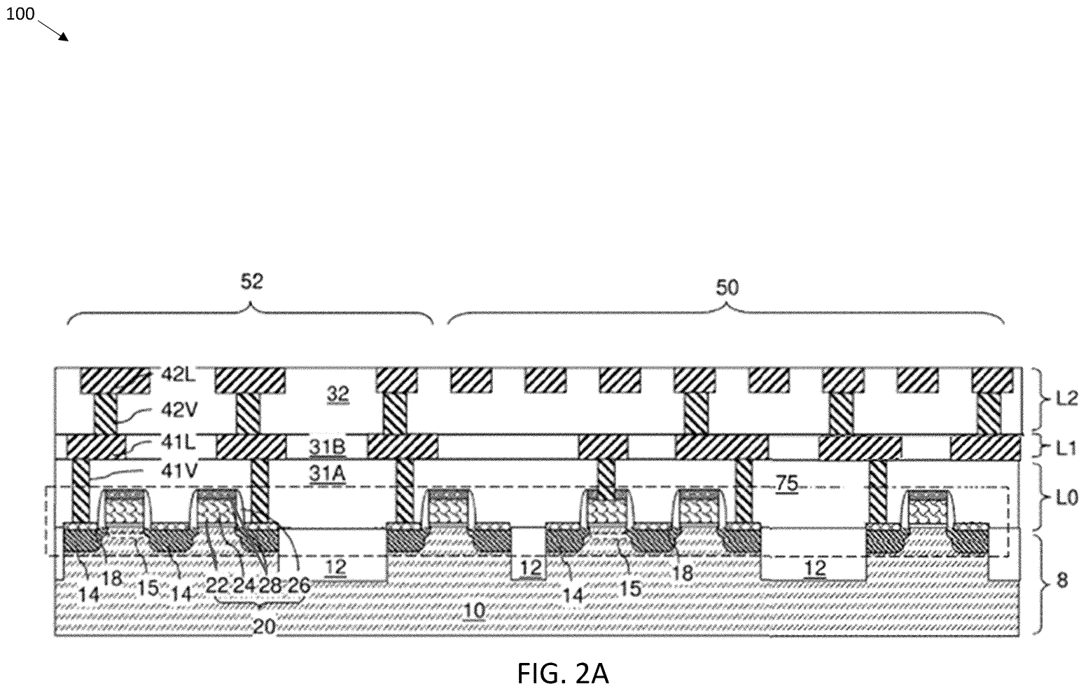

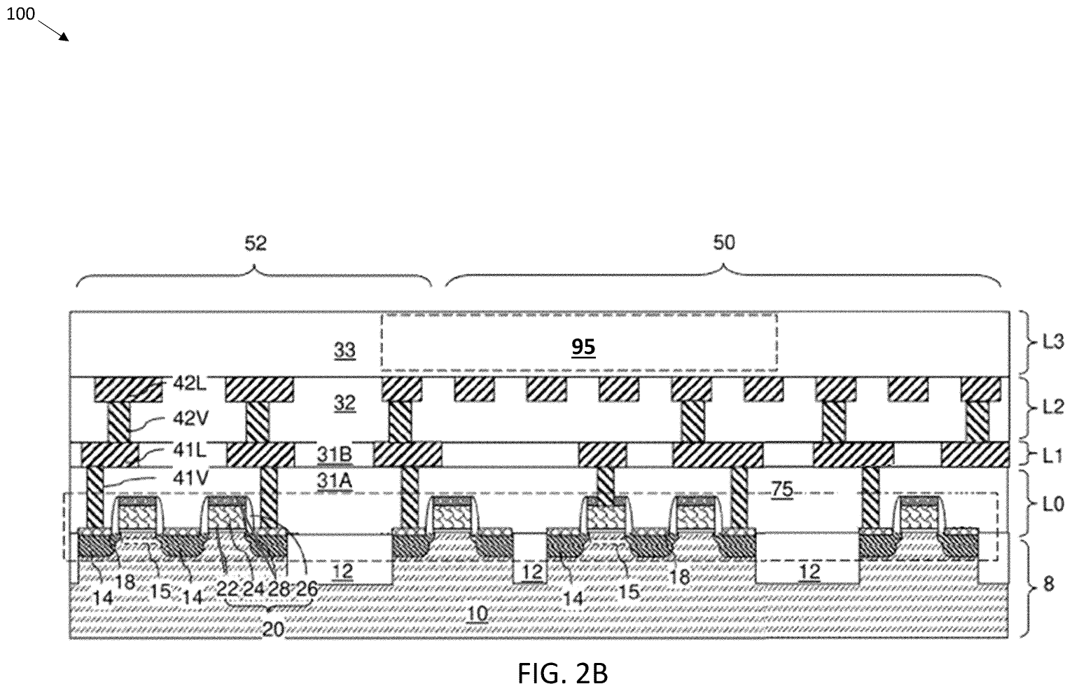

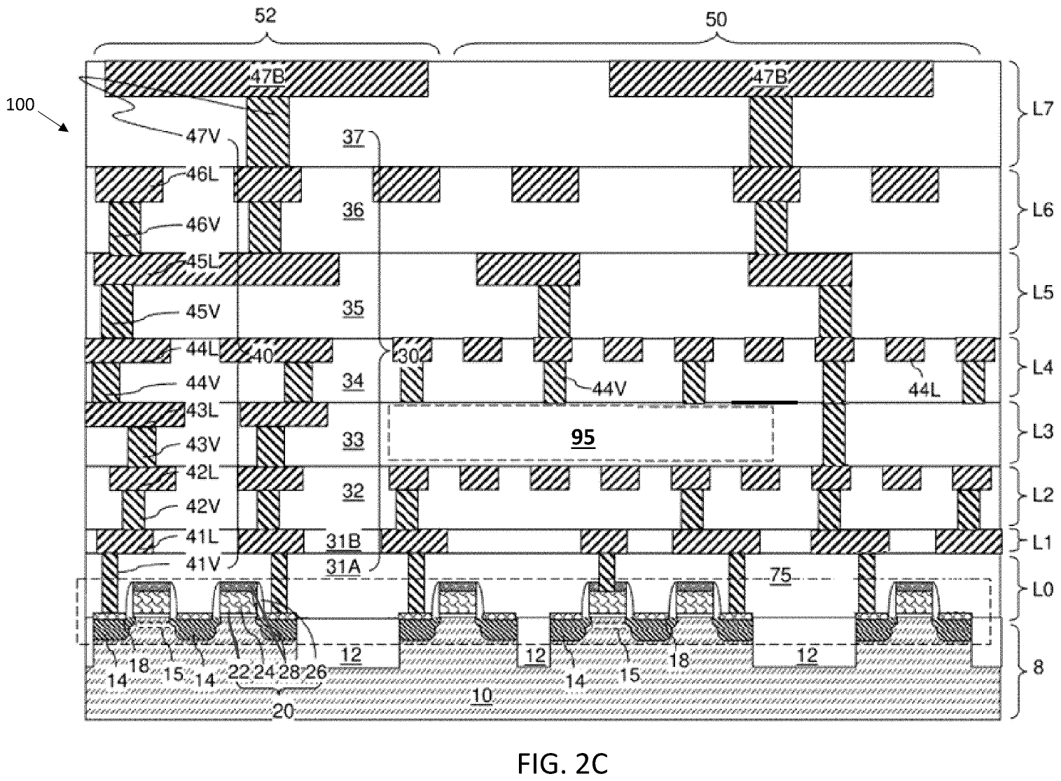

FIG. 2A is a vertical cross-sectional view of an exemplary semiconductor device structure 100 after formation of complementary metal-oxide-semiconductor (CMOS) transistors, metal interconnect structures embedded in dielectric material layers, and a connection-via-level dielectric material layer, according to some embodiments of the present disclosure. The exemplary semiconductor device structure 100 includes a substrate 8 that contains a semiconductor material layer 10. The substrate 8 may include a bulk semiconductor substrate such as a silicon substrate in which the semiconductor material layer continuously extends from a top surface of the substrate 8 to a bottom surface of the substrate 8, or a semiconductor-on-insulator layer including the semiconductor material layer 10 as a top semiconductor layer overlying a buried insulator layer. Shallow trench isolation structures 12 including a dielectric material (e.g., silicon oxide) may be formed in an upper portion of the substrate 8. Suitable doped semiconductor wells, such as p-type wells and n-type wells, may be formed within each area that may be laterally enclosed by a portion of the shallow trench isolation structures 12. Logic devices, such as CMOS transistors, may be formed over the top surface of the substrate 8. Each logic device may include source/drain regions 14, a semiconductor channel 15 that includes a surface portion of the substrate 8 extending between the source/drain regions 14, and a gate structure 20. Source/drain region(s) may refer to a source or a drain, individually or collectively dependent upon the context. In this disclosure, a source and a drain are interchangeably used, and the structures thereof are substantially the same. Each gate structure 20 may include a gate dielectric 22, a gate electrode strip 24, a gate cap dielectric 28, and a dielectric gate spacer 26. An optional source/drain metal-semiconductor alloy region 18 may be formed on each source/drain region 14. While planar field effect transistors (FETs) are illustrated, implementations of some aspects of the present disclosure are equally applicable to logic devices using other type of field effect transistors devices, such as three-dimensional fin-like FETs (FinFETs), gate-all-around (GAA) devices (e.g., Horizontal Gate All Around (HGAA) FETs, Vertical Gate All Around (VGAA) FETs), vertical FETs, forksheet FETs, or complementary FETs (CFETs), etc. A person having ordinary skill in the art will readily understand other modifications that may be made are contemplated within the scope of this disclosure.

The exemplary semiconductor device structure 100 may include a memory array region 50 in which an array of memory elements is to be subsequently formed, and a peripheral region 52 in which logic devices that support operation of the array of memory elements may be formed. In one embodiment, devices (such as field effect transistors) in the memory array region 50 may include bottom electrode access transistors that provide access to bottom electrodes of memory cells to be subsequently formed. Top electrode access transistors that provide access to top electrodes of memory cells to be subsequently formed may be formed in the peripheral region 52 at this processing step. Devices (such as field effect transistors) in the peripheral region 52 may provide functions that may be needed to operate the array of memory cells to be subsequently formed. Specifically, devices in the peripheral region may be configured to control the programming operation, the erase operation, and the sensing (read) operation of the array of memory cells. For example, the devices in the peripheral region may include a sensing circuitry and/or a top electrode bias circuitry. The devices formed on the top surface of the substrate 8 may include CMOS transistors and optionally additional semiconductor devices (such as resistors, diodes, capacitors, etc.), and are collectively referred to as CMOS circuitry 75.

Various interconnect-level structures may be subsequently formed, which may be referred to as lower interconnect-level layers (L0, L1, L2). The lower interconnect-level layers (L0, L1, L2) may include an interconnect-level layer L0, a first interconnect-level layer L1, and a second interconnect-level layer L2. The dielectric material layers may include, for example, a contact-level dielectric material layer 31A, a first metal-line-level dielectric material layer 31B, and a second line-and-via-level dielectric material layer 32. Various metal interconnect structures embedded in dielectric material layers are subsequently formed over the substrate 8 and the devices (such as field effect transistors). The metal interconnect structures may include device contact via structures 41V formed in the contact-level dielectric material layer 31A (interconnect-level layer L0) and contact a respective component of the CMOS circuitry 75, first metal line structures 41L formed in the first metal-line-level dielectric material layer 31B (interconnect-level layer L1), first metal via structures 42V formed in a lower portion of the second line-and-via-level dielectric material 32, second metal line structures 42L formed in an upper portion of the second line-and-via-level dielectric material layer 32 (interconnect-level layer L2).

Each of the dielectric material layers (31A, 31B, and 32) may include a dielectric material such as undoped silicate glass, a doped silicate glass, organosilicate glass, amorphous fluorinated carbon, porous variants thereof, or combinations thereof. Each of the metal interconnect structures (41V, 41L, 42V, and 42L) may include at least one conductive material, which may be a combination of a metallic liner layer (such as a metallic nitride or a metallic carbide) and a metallic fill material. Each metallic liner layer may include TiN, TaN, WN, TiC, TaC, and WC, and each metallic fill material portion may include W, Cu, Al, Co, Ru, Mo, Ta, Ti, alloys thereof, and/or combinations thereof. Other suitable materials within the contemplated scope of disclosure may also be used. In one embodiment, the first metal via structures 42V and the second metal line structures 42L may be formed as integrated line and via structures by a dual damascene process.

The dielectric material layers (31A, 31B, and 32) may be located at a lower level relative to an array of memory cells to be subsequently formed. As such, the dielectric material layers (31A, 31B, and 32) are herein referred to as lower-level dielectric material layers, i.e., dielectric material layer located at a lower level relative to the array of memory cells to be subsequently formed. The metal interconnect structures (41V, 41L, 42V, and 42L) are herein referred to lower-level metal interconnect structures. A subset of the metal interconnect structures (41V, 41L, 42V, and 42L) includes lower-level metal lines (such as the third metal line structures 42L) that are embedded in the lower-level dielectric material layers and having top surfaces within a horizontal plane including a topmost surface of the lower-level dielectric material layers. Generally, the total number of metal line levels within the lower-level dielectric material layers (31A, 31B, and 32) may be in a range from 1 to 5.

The exemplary semiconductor device structure 100 may include various devices regions, which may include a memory array region 50 in which at least one array of non-volatile memory cells may be subsequently formed. For example, the at least one array of non-volatile memory cells may include ferroelectric random-access memory (FeRAM), resistive random-access memory (RRAM or ReRAM), magnetic/magneto-resistive random-access memory (MRAM), and phase-change memory (PCM) devices, etc. The exemplary semiconductor device structure 100 may also include a peripheral logic region 52 in which electrical connections between each array of non-volatile memory cells and a peripheral circuit including field effect transistors may be subsequently formed. Areas of the memory array region 50 and the logic region 52 may be employed to form various elements of the peripheral circuit.

In FIG. 2B, an array 95 of non-volatile memory cells and/or ferroelectric memory cell devices is formed in the memory array region 50 over the second interconnect-level layer L2. The details for the structure and the processing steps for the array 95 of non-volatile ferroelectric memory cells are subsequently described in detail below. A third interconnect level dielectric material layer 33 may be formed during formation of the array 95 of non-volatile ferroelectric memory cells. The set of all structures formed at the level of the array 95 of non-volatile memory cells and/or ferroelectric memory cell devices is herein referred to as a third interconnect-level layer L3.

In FIG. 2C, third interconnect-level metal interconnect structures (43V, 43L) may be formed in the third interconnect level dielectric material layer 33. The third interconnect-level metal interconnect structures (43V, 43L) may include second metal via structures 43V and third metal lines 43L. Additional interconnect-level layers may be subsequently formed, which are herein referred to as upper interconnect-level layers (L4, L5, L6, L7). For example, the upper interconnect-level layers (L4, L5, L6, L7) may include a fourth interconnect-level layer L4, a fifth interconnect-level layer L5, a sixth interconnect-level layer L6, and a seventh interconnect-level layer L7. The fourth interconnect-level layer L4 may include a fourth interconnect level dielectric material layer 34 having formed therein fourth interconnect-level metal interconnect structures (44V, 44L), which may include third metal via structures 44V and fourth metal lines 44L. The fifth interconnect-level layer L5 may include a fifth interconnect level dielectric material layer 35 having formed therein fifth interconnect-level metal interconnect structures (45V, 45L), which may include fourth metal via structures 45V and fifth metal lines 45L. The sixth interconnect-level layer L6 may include a sixth interconnect level dielectric material layer 36 having formed therein sixth interconnect-level metal interconnect structures (46V, 46L), which may include fifth metal via structures 46V and sixth metal lines 46L. The seventh interconnect-level layer L7 may include a seventh interconnect level dielectric material layer 37 having formed therein sixth metal via structures 47V (which are seventh interconnect-level metal interconnect structures) and metal bonding pads 47B. The metal bonding pads 47B may be configured for solder bonding (which may employ C4 ball bonding or wire bonding), or may be configured for fusion or hybrid bonding process (such as an insulator-to-insulator, a metal-to-metal, or an insulator-to-metal bonding).

Each interconnect level dielectric material layer may be referred to as an interconnect level dielectric (ILD) layer 30 (i.e., 31A, 31B, 32, 33, 34, 35, 36, and 37). Each interconnect-level metal interconnect structures may be referred to as a metal interconnect structure 40. Each contiguous combination of a metal via structure and an overlying metal line located within a same interconnect-level layer (L2-L7) may be formed sequentially as two distinct structures by employing two single damascene processes, or may be simultaneously formed as a unitary structure employing a dual damascene process. Each of the metal interconnect structure 40 (i.e., 41V, 41L, 42V, 42L, 43V, 43L, 44V, 44L, 45V, 45L, 46V, 46L, 47V, 47B) may include a respective metallic liner (such as a layer of TiN, TaN, or WN) and a respective metallic fill material (such as W, Cu, Co, Mo, Ru, other elemental metals, or an alloy or a combination thereof). Various etch stop dielectric material layers and dielectric capping layers may be inserted between vertically neighboring pairs of ILD layers 30, or may be incorporated into one or more of the ILD layers 30.

While the present disclosure is described employing an embodiment in which the array 95 of non-volatile memory cells and/or ferroelectric memory cell devices are formed as a component of a third interconnect-level layer L3, embodiments are expressly contemplated herein in which the array 95 of non-volatile memory cells and/or ferroelectric memory cell devices may be formed as components of any other interconnect-level layer (e.g., L1-L7). Further, while the present disclosure is described using an embodiment in which a set of eight interconnect-level layers are formed, embodiments are expressly contemplated herein in which a different number of interconnect-level layers is used. In addition, embodiments are expressly contemplated herein in which two or more arrays 95 of non-volatile memory cells and/or ferroelectric memory cell devices may be provided within multiple interconnect-level layers in the memory array region 50. While the present disclosure is described employing an embodiment in which an array 95 of non-volatile memory cells and/or ferroelectric memory cell devices may be formed in a single interconnect-level layer, embodiments are expressly contemplated herein in which an array 95 of non-volatile memory cells and/or ferroelectric memory cell devices may be formed over two vertically adjoining interconnect-level layers.

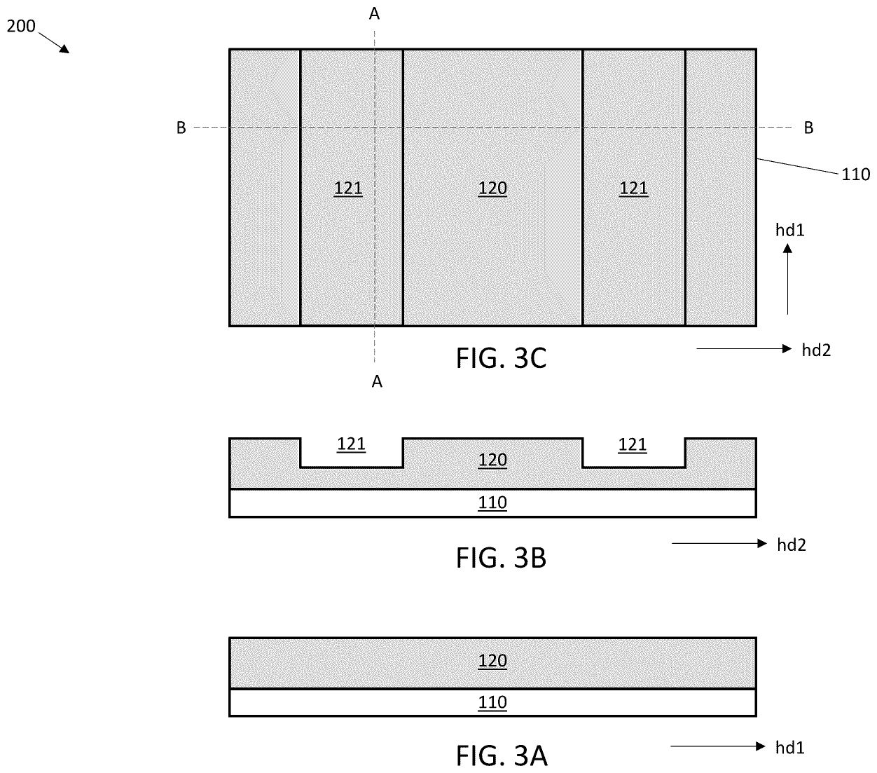

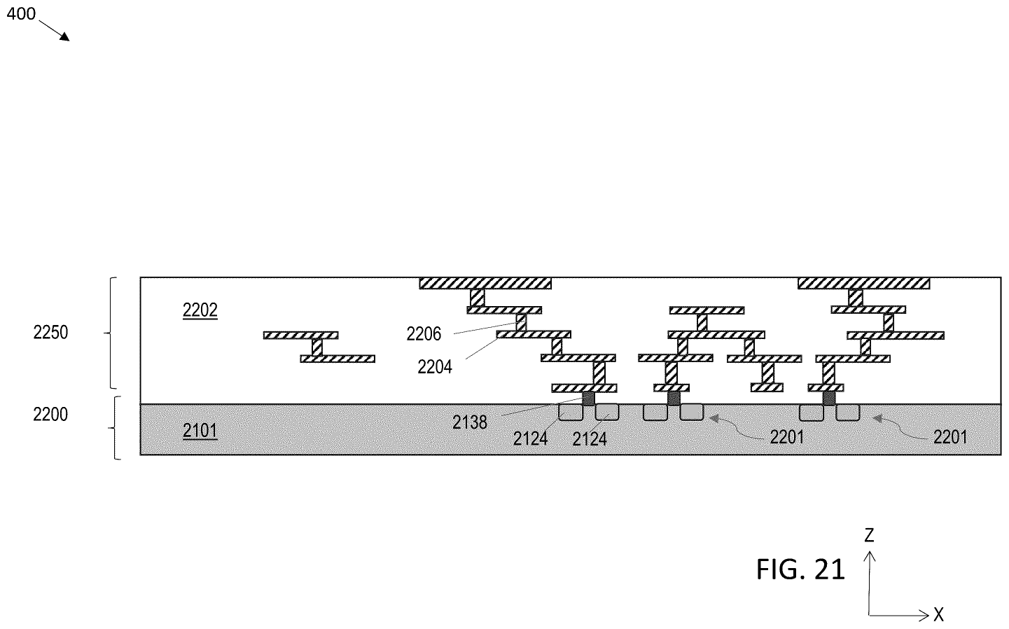

FIG. 3C is a horizontal cross-sectional view of an exemplary semiconductor device structure 200 after etching and patterning metal line trenches in the first dielectric material layer according to an embodiment of the present disclosure. FIG. 3A is a vertical cross-sectional view of the exemplary semiconductor device structure 200 along the plane A-A of FIG. 3C. FIG. 3B is a vertical cross-sectional view of the exemplary semiconductor device structure 200 along the plane B-B of FIG. 3C. The exemplary semiconductor device structure 200 may be fabricated to include a plurality of vertical-type gate-all-around devices, each of which may function as a capacitor or a charge storage memory device. Referring to FIGS. 3A-3C, a first dielectric material layer 120 may be deposited on a substrate 110. The substrate 110 may be any suitable substrate, such as a semiconductor device substrate. In other embodiments, the substrate 110 may be the second or third interconnect level dielectric material 32, 33 as shown in FIG. 2C. In some embodiments, the substrate 110 may be the substrate 2101 to be discussed below in FIGS. 21-28. The first dielectric material layer 120 may include a dielectric material such as silicon oxide (SiO₂), undoped silicate glass, a doped silicate glass, organosilicate glass, amorphous fluorinated carbon, porous variants thereof, or combinations thereof. The first dielectric material layer 120 may be deposited through any of a number of suitable deposition process or grown over the ILD layer 30. A photoresist layer (not shown) may be applied over the first dielectric material layer 120 and may be patterned to form trenches 121 within areas of the first dielectric material layer 120 where metal lines are subsequently formed. For example, the photoresist pattern may be formed by depositing a photoresist material and then patterning the deposited photoresist material using photolithography. The patterned photoresist may mask portions of the first dielectric material layer 120 to protect these portions in a subsequent etch process. An etch process is then performed to form metal line trenches 121 in the first dielectric material layer 120. For example, the first dielectric material layer 120 may be etched using a wet etch, a dry etch, or a combination thereof. In one embodiment, each metal line trench 121 can be located within an upper portion of the first dielectric material layer 120. The metal line trenches 121 can laterally extend along a first horizontal direction hd1, and can be laterally spaced apart along a second horizontal direction hd2 that is perpendicular to the first horizontal direction hd1. The photoresist may then be removed, for example, by ashing or a chemical process.

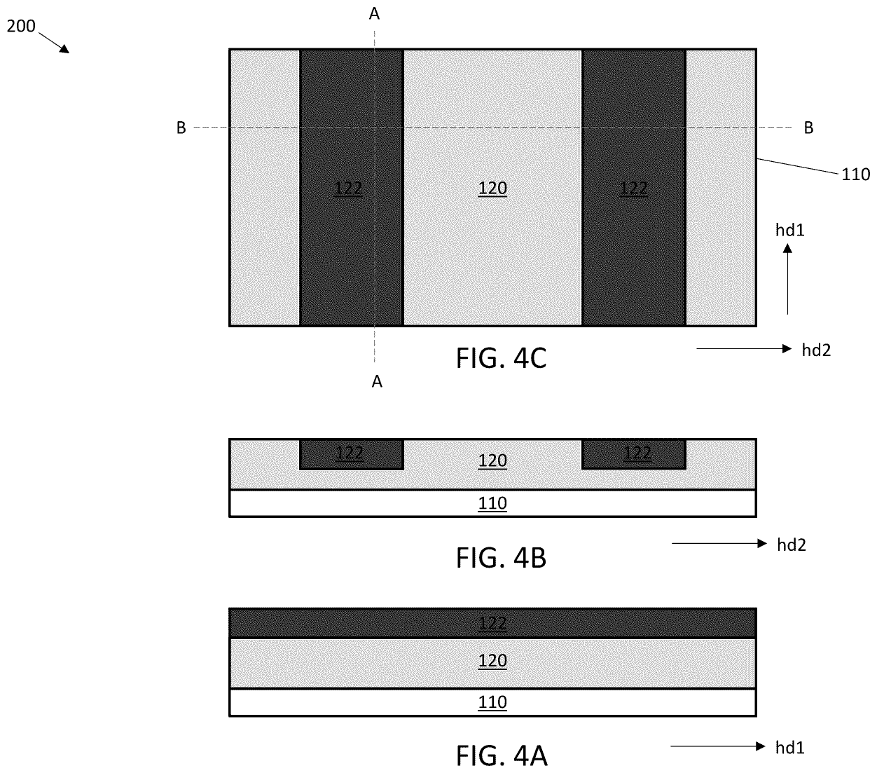

FIG. 4C is a horizontal cross-sectional view of the exemplary semiconductor device structure 200 after depositing and planarizing a conductive metal material in the metal line trench to form metal lines, according to an embodiment of the present disclosure. FIG. 4A is a vertical cross-sectional view of the exemplary semiconductor device structure 200 along the plane B-B of FIG. 4C. FIG. 4B is a vertical cross-sectional view of the exemplary semiconductor device structure 200 along the plane A-A of FIG. 4C. Referring to FIGS. 4A-4C, metal lines 122 may be formed in the metal line trenches 121. An electrically conductive material may be deposited over the first dielectric material layer 120 in order to fill the metal line trenches 121. The metal lines 122 may be formed from an electrically conductive metal material such as, copper, aluminum, zirconium, titanium, titanium nitride, tungsten, tantalum, tantalum nitride, ruthenium, palladium, platinum, cobalt, nickel, iridium, alloys thereof, or the like. The metal lines 122 may be formed by depositing a layer of conductive material using any suitable deposition process, such as a chemical vapor deposition (CVD) process, a physical vapor deposition (PVD) process, an atomic layer deposition (ALD) process, a high density plasma CVD (HDPCVD) process, a metalorganic CVD (MOCVD) process, a plasma enhanced CVD (PECVD) process, a sputtering process, or the like.

A planarization process, such as a chemical mechanical polishing (CMP) process or the like, may then be performed to remove excess electrically conductive metal material from the surface of the first dielectric material layer 120 and to render the top surface of metal lines 122 co-planar with the top surface of the first dielectric material layer 120. In one embodiment, each metal line 122 may be located within an upper portion of the first dielectric material layer 120. The metal lines 122 may laterally extend along a first horizontal direction hd1, and can be laterally spaced apart along the second horizontal direction hd2 that is perpendicular to the first horizontal direction hd1. In some embodiments, one or more metal lines 122 may be grounded. In cases where the substrate 101 functions as the substrate 2101 to be discussed below in FIGS. 21-28, the metal lines 122 may be the conducive features 2198 that are to be connected to conductive features 2197 serving as a power rail.

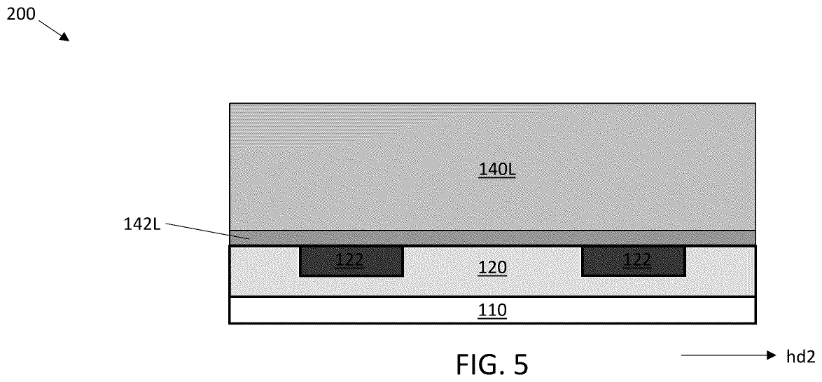

FIGS. 5-17 are vertical cross-sectional views of the exemplary semiconductor device structure 200 along a first horizontal direction hd1 (i.e., plane B-B) during various stages of manufacturing, according to some embodiments of the present disclosure. In FIG. 5, after the metal lines 122 are formed, a first electrode layer 142L and a semiconductor channel material layer 140L are sequentially deposited over the metal lines 122 and the substrate 110. The first electrode layer 142L may be patterned to form a bottom electrode over the metal line 122. The bottom electrode may serve as a source/drain for a transistor, or an electrode for a capacitor (e.g., a vertical-type GAA capacitor device), which can be used as a charge storage memory device (e.g., a FeRAM memory cell). The first electrode layer 142L may be formed from electrically conductive materials such as, copper, aluminum, zirconium, titanium, titanium nitride, tungsten, tantalum, tantalum nitride, ruthenium, palladium, platinum, cobalt, nickel, iridium, alloys thereof, or the like. The first electrode layer 142L may be formed by any suitable process, such as ALD, PVD or electro-plating. In one example, the first electrode layer 142L is titanium nitride formed by an ALD process.

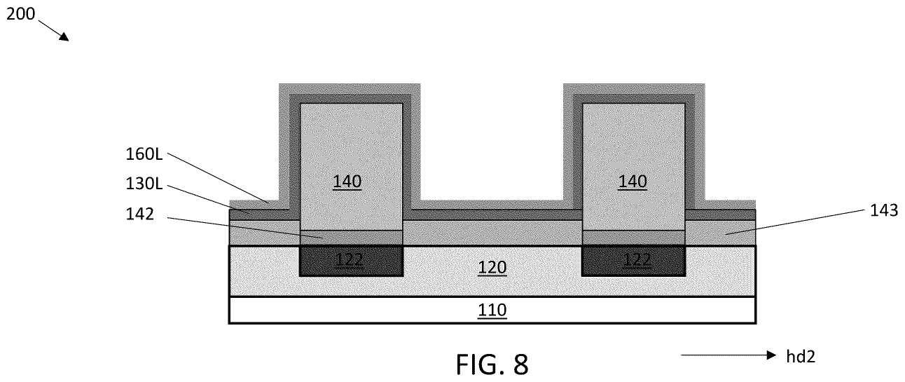

The semiconductor channel material layer 140L may include polysilicon, amorphous silicon, or a semiconducting oxide, such as InGaZnO (IGZO), indium tin oxide (ITO), InWO, InZnO, InSnO, GaOx, InOx, or the like. In one embodiment, the semiconductor channel material layer 140L is formed of IGZO. The IGZO may be “intrinsic,” or may include dopants, depending on the application. The semiconductor material layer 140L is to be surrounded by a ferroelectric dielectric layer (e.g., a ferroelectric dielectric layer 130L shown in FIG. 8) and a gate electrode layer (e.g., an electrode material layer 160L shown in FIG. 8) to form a ferroelectric memory cell. The semiconductor material layer 140L may be deposited using any suitable deposition process, such as a CVD process, a PVD process, an ALD process, a HDPCVD process, a MOCVD process, a PECVD process, a sputtering process, or the like.

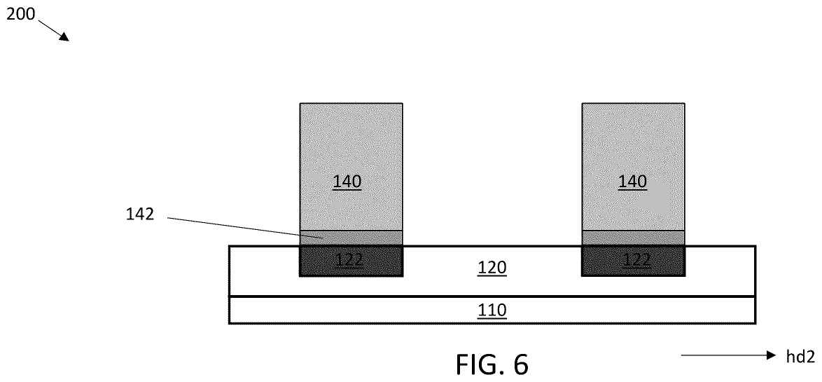

In FIG. 6, the semiconductor channel material layer 140L and the first electrode layer 142L are patterned to form a semiconductor channel 140 and a bottom electrode 142. A two-dimensional array of mask layer (not shown) such as a photoresist may be deposited over the semiconductor channel material layer 140L and the first electrode layer 142L. A photolithography process is performed to transfer a pattern over the mask layer. An etch process is then used to selectively remove portions of the semiconductor channel material layer 140L and the first electrode layer 142L. By etching unmasked portions of the semiconductor channel material layer 140L and the first electrode layer 142L, the semiconductor channel material layer 140L and the first electrode layer 142L are patterned to form two-dimensional array of semiconductor channel 140 and the bottom electrode 142. As can be seen, each row of semiconductor channel 140 and the bottom electrode 142 are formed over a respective one of the metal lines 122.

The resulting semiconductor channel 140 and the bottom electrode 142 may be in the form of a column, pillar, a nanowire, or a quadrilateral shape. The semiconductor channel 140 and the bottom electrode 142 as shown may be vertically aligned with respect to the first dielectric material layer 120. In other words, a long axis of each semiconductor channel 140 and the bottom electrode 142 may extend perpendicular to a plane of the first dielectric material 120 and/or an underlying semiconductor substrate. After the semiconductor channel 140 and the bottom electrode 142 are formed, the mask layer may be removed by ashing or any suitable process.

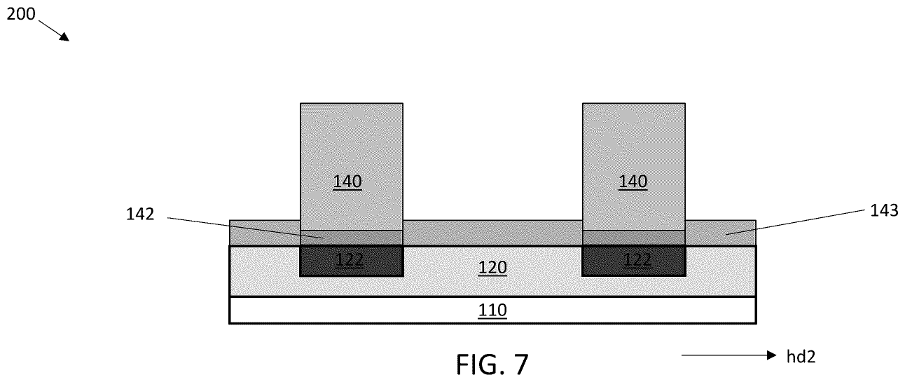

In FIG. 7, a first etch stop layer 143 is selectively formed on the exposed surface of the first dielectric material 120. The first etch stop layer 143 may include a material different from the first dielectric material 120 in order to have different etch selectivity compared to the first dielectric material 120. In some embodiments, the first etch stop layer 143 is made of a dielectric material, such as an oxide, a nitride, a metal oxide, a metal nitride, or a combination thereof. Suitable materials for the first etch stop layer 143 may include, but not limited to, silicon nitride, silicon carbide, oxygen-doped silicon carbide (ODC), silicon carbon nitride, silicon oxynitride, carbon nitride, silicon oxide, silicon carbon oxide, and aluminum oxide, etc. The first etch stop layer 143 may be selectively formed on the first dielectric material 120 since they both include dielectric material, instead of the semiconductor or metallic material used by the semiconductor channel 140 and the bottom electrode 142. The first etch stop layer 143 may be a single layer or a multi-layer structure including two or more layers of dielectric material discussed herein. In one exemplary embodiment, the first etch stop layer 143 is silicon oxynitride. The first etch stop layer 143 may be formed by any suitable process, such as CVD, ALD, PVD, PEALD, or PECVD. The first etch stop layer 143 may be deposited to a height so that a top surface of the first etch stop layer 143 is at an elevation slightly higher than an interface defined by the semiconductor channel 140 and the bottom electrode 142.

In FIG. 8, a ferroelectric dielectric layer 130L and an electrode material layer 160L are sequentially formed over the first etch stop layer 143 and the two-dimensional array of semiconductor channel 140. The ferroelectric dielectric layer 130L may be formed of any suitable ferroelectric material, such as hafnium oxide (HfO₂), zirconium oxide (ZrO₂), hafnium zirconium oxide (HfZrO₂), aluminum scandium nitride (AlScN), lead zirconium oxide (PbZrO₃), Pb[ZrxTi1−x]O₃, (0≤x≤1) (PZT), BaTiO₃, PbTiO₃, PbNb₂O₆, LiNbO₃, LiTaO₃, polyvinylidene fluoride (PVDF), potassium dihydrogen phosphate (KDP), PbMg⅓Nb₂/3O₃ (PMN), PbSc½Ta½O₃PbSc½Ta½O₃ (PST), SrBi₂Ta₂O₉ (SBT), Bi½Na½TiO₃Bi½Na½TiO₃, combinations thereof, or the like. Other dielectric material, such as silicon oxide or a high-k dielectric material (e.g., a material having a dielectric constant greater than 3.9) may also be used. Suitable high-k dielectric materials may include, but are not limited to, silicon nitride, hafnium silicon oxide (HfSiO), hafnium tantalum oxide (HfTaO), hafnium titanium oxide (HfTiO), hafnium zirconium oxide (Hf_{0.5}Zr_{0.5}O₂) (HZO)), tantalum oxide (Ta₂O₅), aluminum oxide (Al₂O₃), hafnium dioxide-alumina (HfO₂—Al₂O₃). In one exemplary embodiment, the ferroelectric dielectric layer 130L is HZO. The ferroelectric dielectric layer 130L may be deposited by a conformal deposition, such as an ALD process, or any suitable deposition process.

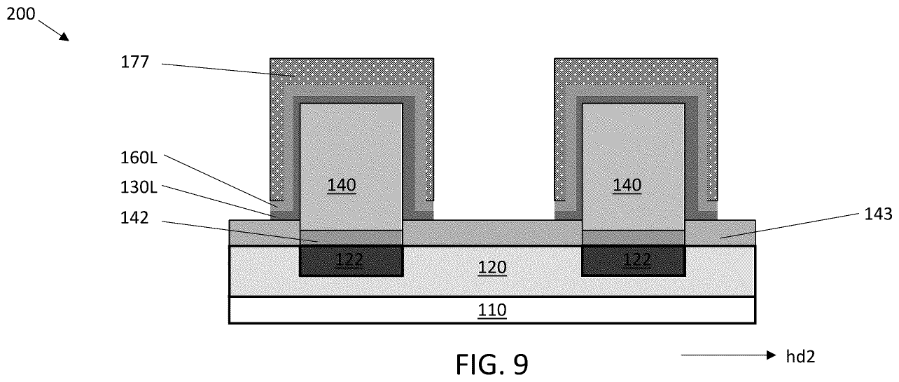

In FIG. 9, portions of the ferroelectric dielectric layer 130L and the electrode material layer 160L are patterned. A two-dimensional array of etch mask material such as a photoresist 177 may be applied over the electrode material layer 160L overlying the respective column of semiconductor channels 140. A photolithography process may be performed to transfer a pattern over the photoresist 177. By anisotropically etching unmasked portions of the ferroelectric dielectric layer 130L and the electrode material layer 160L employing the two-dimensional array of photoresist 177 as an etch mask, the remaining portions of the ferroelectric dielectric layer 130L and the electrode material layer 160L may be patterned, resulting in a conformal layer structure that surrounds the respective semiconductor channels 140. Portions of the first etch stop layer 143, the ferroelectric dielectric layer 130L and the electrode material layer 160L are exposed.

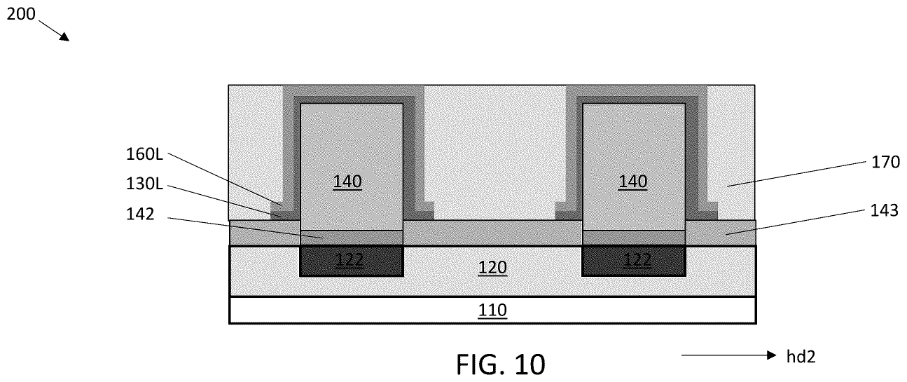

In FIG. 10, the photoresist 177 is removed and a first dielectric layer 170 is deposited on exposed surfaces of the electrode material layer 160L, the ferroelectric dielectric layer 130L, and the first etch stop layer 143. The photoresist 177 may be removed by ashing or any suitable process. Upon removal of the photoresist 177, portions of the electrode material layer 160L and the ferroelectric dielectric layer 130L may remain at the corner of the semiconductor channel 140 and the first etch stop layer 143, forming a footing extended laterally from the electrode material layer 160L and the ferroelectric dielectric layer 130L that are deposited on the sidewall of the semiconductor channels 140. The first dielectric layer 170 may be formed of silicon oxide or any suitable dielectric material. In some embodiments, the first dielectric layer 170 is formed of the same material used for forming the first dielectric material layer 120. The first dielectric layer 170 may be deposited to a height over the top surface of the electrode material layer 160L using any suitable deposition technique, such as a CVD process or a PECVD process. After the first dielectric layer 170 is formed, a CMP process is performed to planarize the upper surface of the first dielectric layer 170. The CMP process may be performed until the electrode material layer 160L is exposed.

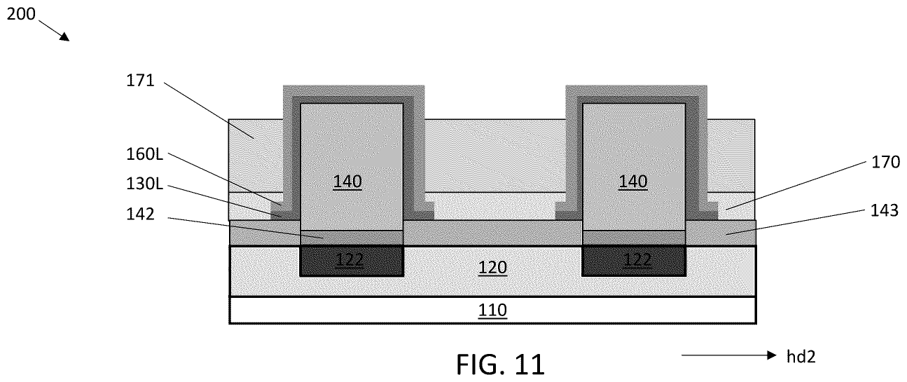

In FIG. 11, an etch back process is performed to remove a portion of the first dielectric layer 170. The etch back process may be a dry etch, a wet etch, or a combination of thereof. The etch back process is a selective etch process which removes the first dielectric layer 170 but not the electrode material layer 160L. The etch back process may be performed so that a top surface of the first dielectric layer 170 is at an elevation slightly higher than an upper portion of the footing of the electrode material layer 160L and the ferroelectric dielectric layer 130L (e.g., the electrode material layer 160L extended laterally from the electrode material layer 160L and the ferroelectric dielectric layer 130L that are deposited on the sidewall of the semiconductor channels 140).

After the etch back process, a metal layer 171 is formed on exposed surfaces of the first dielectric layer 170 and the electrode material layer 160L. The metal layer 171 serves as a word line for the FeRAM memory cell. The metal layer 171 may include one or more layers of electrical conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. In one embodiment, the metal layer 171 is tungsten. The metal layer 171 may be formed by CVD, ALD, electro-plating, or other suitable deposition technique.

Then, the metal layer 171 is recessed using an etch back process, such as a dry etch, a wet etch, or a combination thereof. The etch back process may be performed so that a top surface of the metal layer 171 is lower than the top surface of the semiconductor channels 140. The etch back process is a selective etch process which removes the metal layer 171 but not the electrode material layer 160L.

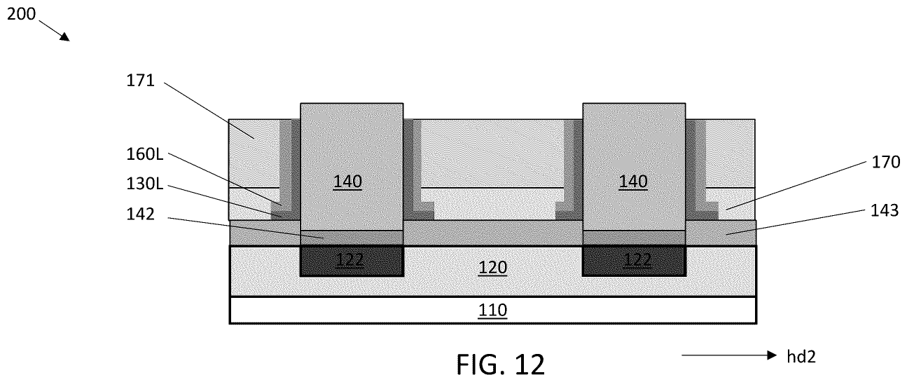

In FIG. 12, an etch back process is performed to remove portions of the electrode material layer 160L and the ferroelectric dielectric layer 130L. The etch back process may be a selective etch process which removes the electrode material layer 160L and the ferroelectric dielectric layer 130L without substantially affecting the semiconductor channels 140 and the metal layer 171. The etch back process may include an isotropic etch process such as a wet etch process, or an anisotropic etch process such as a reactive ion etch process. The etch back process may be performed until the top surfaces of the electrode material layer 160L and the ferroelectric dielectric layer 130L are substantially co-planar with the top surface of the metal layer 171. After the etch back process, the top surface of the semiconductor channels 140 is at an elevation higher than the top surfaces of the electrode material layer 160L, the ferroelectric dielectric layer 130L, and the metal layer 171. The recess depth of the electrode material layer 160L and the ferroelectric dielectric layer 130L results in the metal layer 171 that surrounds the semiconductor channel 140 (e.g., a pillar-like semiconductor channel 140).

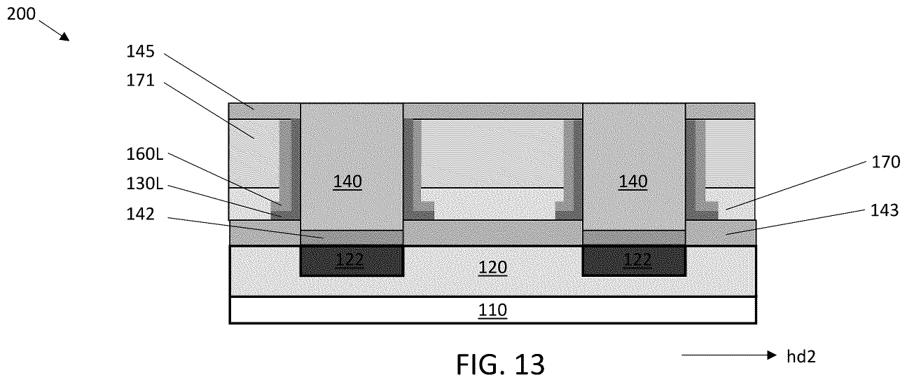

In FIG. 13, a second etch stop layer 145 is deposited on exposed surfaces of the semiconductor channels 140, the electrode material layer 160L, the ferroelectric dielectric layer 130L, and the metal layer 171. The second etch stop layer 145 may be deposited to a height greater than the top surface of the semiconductor channels 140. The second etch stop layer 145 may include the same material as the first etch stop layer 143, and may be formed in the same fashion as the first etch stop layer 143. Thereafter, a CMP process is performed to planarize the upper surface of the second etch stop layer 145. The CMP process may be performed until the semiconductor channels 140 are exposed.

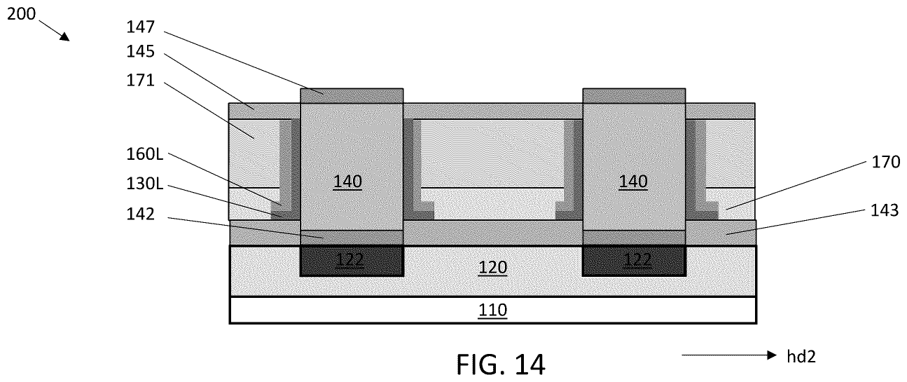

In FIG. 14, a second electrode layer 147 is selectively formed on the semiconductor channels 140. The second electrode layer 147 may be first deposited in a blanket manner and then patterned to form a top electrode. Likewise, the top electrode may serve as a source/drain for a transistor, or an electrode for a capacitor (e.g., a vertical-type GAA capacitor device), which can be used as a charge storage memory device (e.g., a FeRAM memory cell). The second electrode layer 147 may include the same material as the first electrode layer 142L, and may be deposited in the same fashion as the first electrode layer 142L. In one embodiment, the second electrode layer 147 is titanium nitride formed by an ALD process.

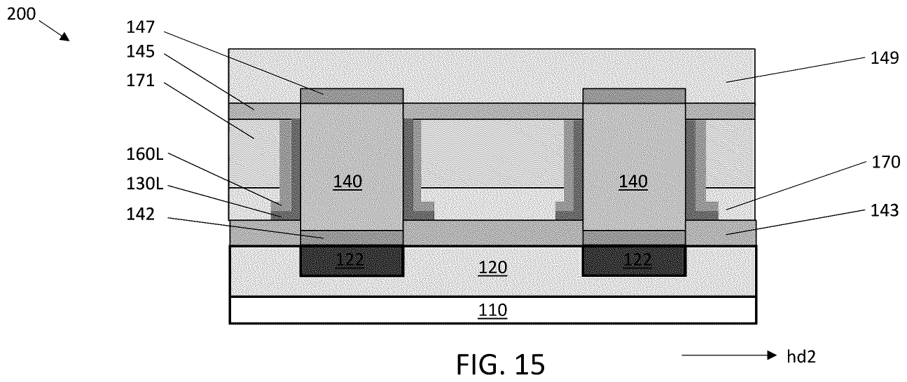

In FIG. 15, a second dielectric layer 172 is formed on exposed surfaces of the second etch stop layer 145 and the second electrode layer 147. The second dielectric layer 172 may include the same material as the first dielectric layer 170, and may be formed in the same fashion as first dielectric layer 170. Upon deposition of the second dielectric layer 172, the second electrode layer 147 is embedded in the second dielectric layer 172.

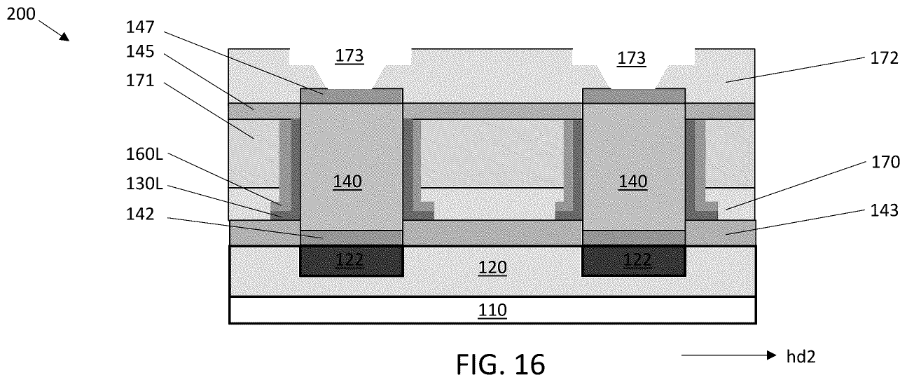

In FIG. 16, openings 173 are formed in and through the second dielectric layer 172. The openings 173 are intended to be filled with an electrically conductive material to form conductive features therein. The openings 173 may be formed by any suitable process, such as one or more etch processes. In some embodiments, the openings 173 may be a result of a dual-damascene process. Each opening 173 may include a trench opening laterally extending along the first horizontal direction hd1 in an upper portion of the second dielectric layer 172. Each opening 173 may also include a via opening formed vertically through the second dielectric layer 172 to expose a portion of the second electrode layer 147.

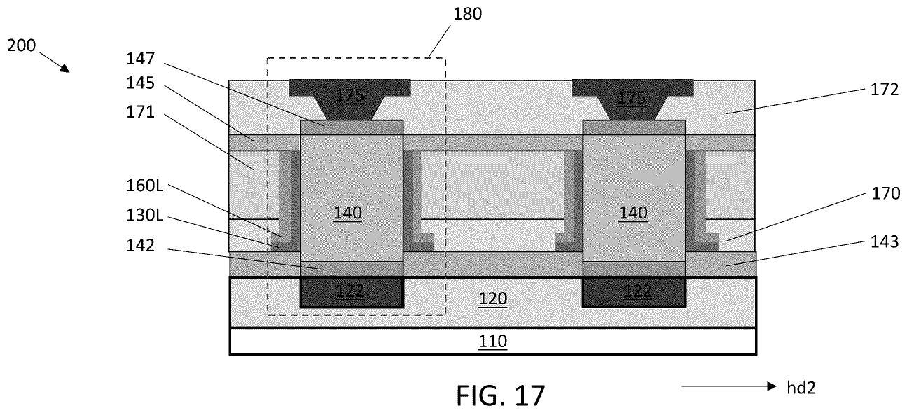

In FIG. 17, an electrically conductive material is formed in the openings 173 to form conductive feature 175. Suitable electrically conductive materials may include, but are not limited to, copper, aluminum, zirconium, titanium, titanium nitride, tungsten, tantalum, tantalum nitride, ruthenium, palladium, platinum, cobalt, nickel, iridium, alloys thereof, or the like. The conductive feature 175 may be formed by CVD, ALD, electro-plating, or other suitable deposition technique. The electrically conductive material fills in the openings 173 and over a top surface of the second dielectric layer 172. Excess portions of the electrically conductive material may be removed from above the top surface of the second dielectric layer 172 by a CMP process. The conductive feature 175 filling a respective trench opening in the second dielectric layer 172 may operate as an effective bit line. Each of the conductive feature 175 is formed on the second electrode layer 147, which is in direct contact with a respective row of top surfaces of the semiconductor channels 140. Therefore, the conductive features 175 is formed over the two-dimensional array of semiconductor channels 140, wherein each of the conductive features 175 is formed directly over the top surfaces of a respective row of pillar-like semiconductor channels 140.

As can be seen, each semiconductor channel 140 is disposed between the first electrode layer 142 (e.g., source) and the second electrode layer 147 (e.g., drain). The second electrode layer 147 is in electrical connection with the conductive feature 175 (e.g., bit line). The semiconductor channel 140 is surrounded by the metal layer 171 (e.g., word line), the electrode material layer 160L, and the ferroelectric dielectric layer 130L, in which the ferroelectric dielectric layer 130L is disposed between and in contact with the semiconductor channel 140 and the electrode material layer 160L. The semiconductor channel 140, the first and second electrode layers 142, 147, the ferroelectric dielectric layer 130L, the electrode material layer 160L, and the metal layer 171 may collectively refer to as a vertical-type gate-all-around (GAA) device structure 180 in which a channel region (vertically disposed between a top source/drain feature and a bottom source/drain feature) is surrounded by a layer of ferroelectric material. The device structure 180 forms a one-transistor (1T) FeRAM circuit that may function as a capacitor or a memory device. The vertical-type GAA device structure 180 provides a large effective area for the capacitor or memory device and increased charge storage capability. Moreover, the use of high-k dielectric material (e.g., hafnium zirconium oxide (HZO)) as the ferroelectric material offers a high ferroelectric polarization to further enhance charge storage capabilities.

In some embodiments, various memory cell devices are electrically connected to form an array of memory cell devices for increase charge storage capacity. The array of memory cell devices may be disposed in a memory array region in an interconnect structure, such as the memory array region 50 over the second interconnect-level layer L2 shown in FIGS. 2B and 2C. Since the array of 1T GAA FeRAM devices are disposed between BEOL metal routings in the interconnect structure that is away from the front-end transistor devices, additional space can be provided for complicated front-end transistor devices, thereby improving the performance of the overall structure.

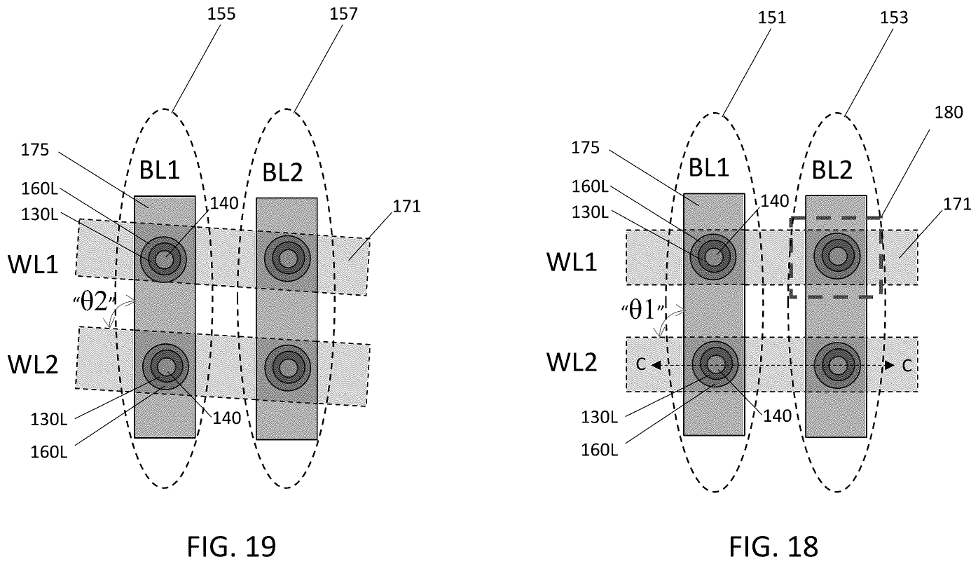

FIG. 18 illustrates a schematic diagram of a layout design 1800, in accordance with the embodiment of FIG. 17. FIG. 17 shows a vertical cross-sectional view of a portion of the exemplary semiconductor device structure 200 taken along the plane C-C shown in FIG. 18. As can be seen, a first set of memory cell devices 151 (e.g., vertical-type GAA device structures 180) is arranged in a first column extending a first direction, a second set of memory cell devices 153 (e.g., vertical-type GAA device structures 180) is arranged in a second column extending along the first direction, wherein the second set of memory cell devices is separated from the first set of memory cell devices. A first bit line (BL1) (e.g., conductive feature 175) coupled to the first set of memory cell devices 151, and extending along the first direction, and a second bit line (BL2) coupled to the second set of memory cell devices 153, and extending along the first direction. A first word line (WL1) (e.g., metal layer 171) is arranged to extend along a second direction that is different from the first direction, and a second word line (WL2) (e.g., metal layer 171) is arranged to extend along the second direction.

The first word line (WL1) and the second word line (WL2) may be disposed in a first interconnect-level dielectric layer. The first bit line (BL1) and the second bit line (BL2) may be disposed in a second interconnect-level dielectric layer that is higher than the first interconnect-level dielectric layer. The first word line (WL1) surrounds a first memory cell device 180 of the first set of memory cell devices 151 and a first memory cell device 180 of the second set of memory cell devices 153. The second word line (WL2) surrounds a second memory cell device 180 of the first set of memory cell devices 151 and a second memory cell device 180 of the second set of memory cell devices 153. In some embodiments, the first bit line (BL1) and the second bit line (BL2) and the first word line (WL1) and second word line (WL2) are formed such that at least the first bit line (BL1) extends along the first direction that is perpendicular to the second direction of the first word line (WL1). That is, an intersection angle “θ1” between the first bit line (BL1) and the first word line (WL1) is about 90 degrees.

FIG. 19 illustrates a schematic diagram of a layout design 1900, in accordance with an alternative embodiment. The embodiment of FIG. 19 is substantially identical to that of FIG. 18 except that the first bit line (BL1) and the second bit line (BL2) are formed in a non-perpendicular relationship with the first word line (WL1) and second word line (WL2), such that an intersection angle “θ2” formed at least between the first bit line (BL1) and the first word line (WL1) is greater or less than 90 degrees. Embodiments shown in FIGS. 18 and 19 can be applied to various embodiments of the present disclosure.

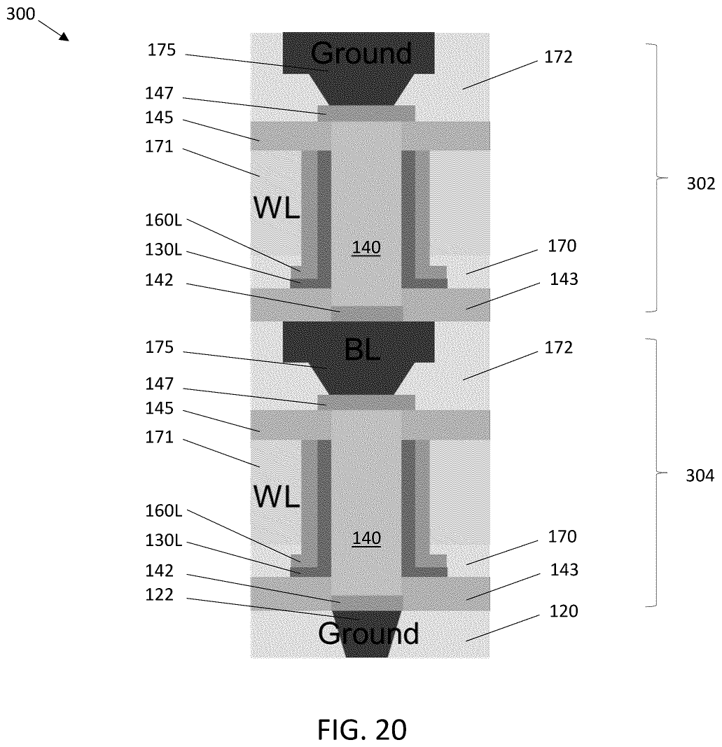

In some embodiments, a third set of memory cell devices (not shown) and a fourth set of memory cell devices (not shown) may be disposed below and aligned with the first and second sets of memory cell devices, respectively. The first and third sets of memory cell devices and the second and fourth sets of memory cell devices may be each configured in a similar fashion as the embodiment shown in FIG. 20, as will be discussed in more detail.

FIG. 20 illustrates a vertical cross-sectional view of an exemplary semiconductor device structure 300, in accordance with some embodiments. The exemplary semiconductor device structure 300 includes two memory cell devices 302, 304 that are vertically stacked and connected. The memory cell devices 302, 304 may be a 1T FeRAM circuit, such as the GAA device structure 180 of FIG. 17, and are electrically connected for increase charge storage capacity. In one embodiment, the first electrode layer 142 of the memory cell device 302 is in contact with the conductive feature 175 of the memory cell device 304, which serves as a bit line. The metal line 122 of the memory cell device 304 and the conductive feature 175 of the memory cell device 302 may be grounded. While two memory cell devices 302, 304 are shown, three or more memory cell devices may be vertically stacked to form an array of memory cell devices. In any case, the exemplary semiconductor device structure 300 or the array of memory cell devices may be disposed between BEOL metal routings or in a memory array region in an interconnect structure, such as the memory array region 50 over the second interconnect-level layer L2 shown in FIGS. 2B and 2C.

FIGS. 21-28 are cross-sectional side views of various stages of manufacturing an exemplary semiconductor device structure 400, in accordance with some embodiments of the present disclosure. In this embodiment, the array of memory cell devices is disposed in the backside interconnect structure to increase the device density and therefore improved charge storage capability. In FIG. 21, a front side interconnect structure 2250 is formed over a device layer 2200. The front side interconnect structure 2250 includes various conductive features, such as a first plurality of conductive features 2204 and second plurality of conductive features 2206, and an intermetal dielectric (IMD) layer 2202 to separate and isolate various conductive features 2204, 2206. In some embodiments, the first plurality of conductive features 2204 are conductive lines and the second plurality of conductive features 2206 are conductive vias. The front side interconnect structure 2250 includes multiple levels of the conductive features 2204, and the conductive features 2204 are arranged in each level to provide electrical paths to the device layer 2200 disposed below.

The device layer 2200 may include a substrate 2101 on which various devices, such as transistors, diodes, imaging sensors, resistors, capacitors, inductors, memory cells, or a combination thereof, may be formed. In some embodiments, the device layer 2200 includes at least one or more logic devices 2201, which can be planar field effect transistors (FETs) as shown, three-dimensional fin-like FETs (FinFETs), gate-all-around (GAA) devices (e.g., Horizontal Gate All Around (HGAA) FETs, Vertical Gate All Around (VGAA) FETs), vertical FETs, forksheet FETs, or complementary FETs (CFETs), multi-bridge channel (MBC) transistors, or any transistors having the gate electrode surrounding the channels. Each logic device 2201 includes S/D regions 2124 and a gate 2138 disposed between a S/D region 2124 serving as source region and a S/D region 2124 serving as a drain regions. The conductive features 2206 provide vertical electrical routing from the device layer 2200 to the conductive features 2204 and between conductive features 2204. For example, the bottom-most conductive features 2206 of the front side interconnect structure 2250 may be electrically connected to conductive contacts (not shown) disposed over the S/D regions 2124 and the gate 2138.

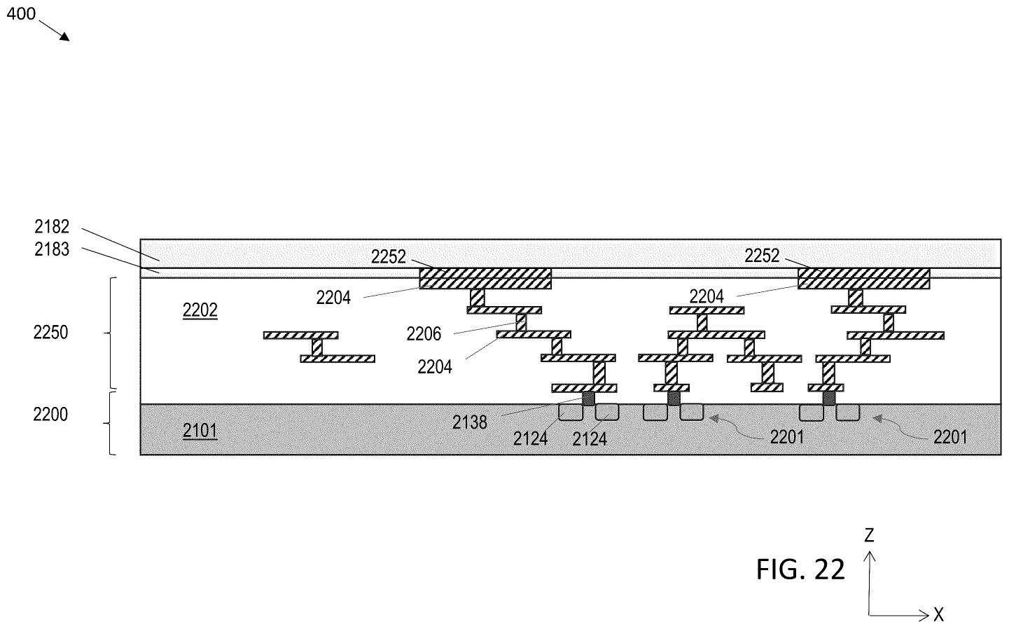

In FIG. 22, the device layer 2200 and the front side interconnect structure 2250 are bonded to a carrier substrate 2182. The carrier substrate 2182 serves to provide mechanical support for the semiconductor device structure 400 so as to facilitate subsequent backside processing of the substrate 2101. The carrier substrate 2182 may include a redistribution layer (RDL) 2183 formed on one side of the carrier substrate 2182. The RDL 2183 may include one or more dielectric layers (not shown) with conductive elements 2252 disposed within the one or more dielectric layers. The conductive elements 2252 may include conductive lines/traces configured to be electrically coupled to the conductive features 2204, 2206 in the front side interconnect structure 2250. In one exemplary embodiment shown in FIG. 22, the front side interconnect structure 2250 is bonded to the RDL 2183 of the carrier substrate 2182 through, for example, an insulator-to-insulator (e.g., dielectric layer of the RDL 2183 to IMD layer 2202 of the front side interconnect structure 2250) and a metal-to-metal (e.g., conductive elements 2252 of the RDL 2183 to conductive features 2204 of the front side interconnect structure 2250) hybrid bonding technology. Additionally or alternatively, the front side interconnect structure 2250 and the RDL 2183 of the carrier substrate 2182 may be bonded together through a bonding layer.

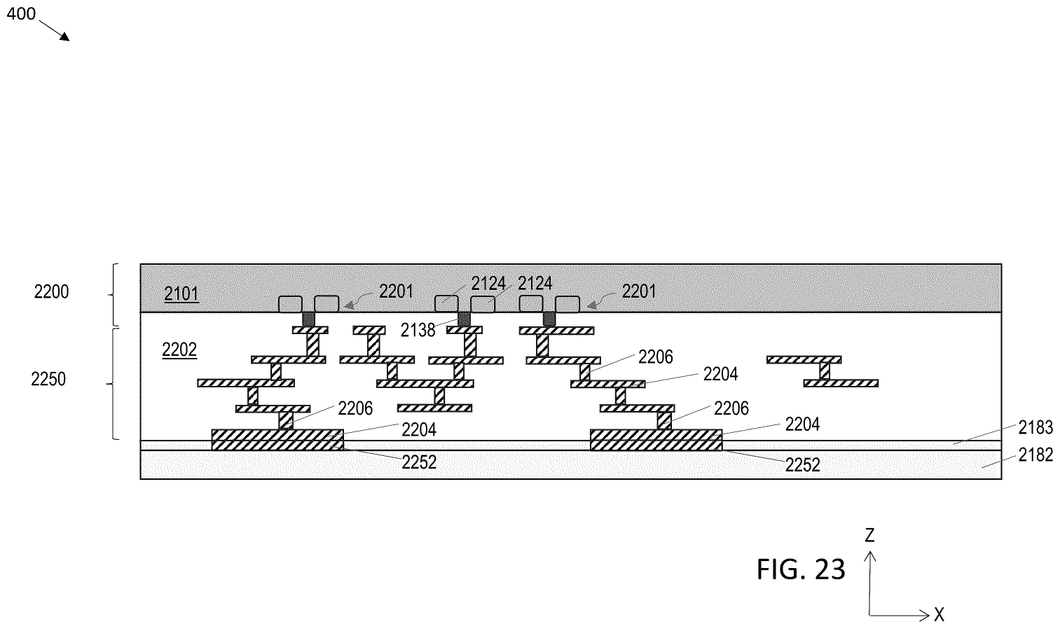

In FIG. 23, the semiconductor device structure 400 is flipped over so that the carrier substrate 2182 is disposed at the bottom while a backside of the substrate 2101 is facing up.

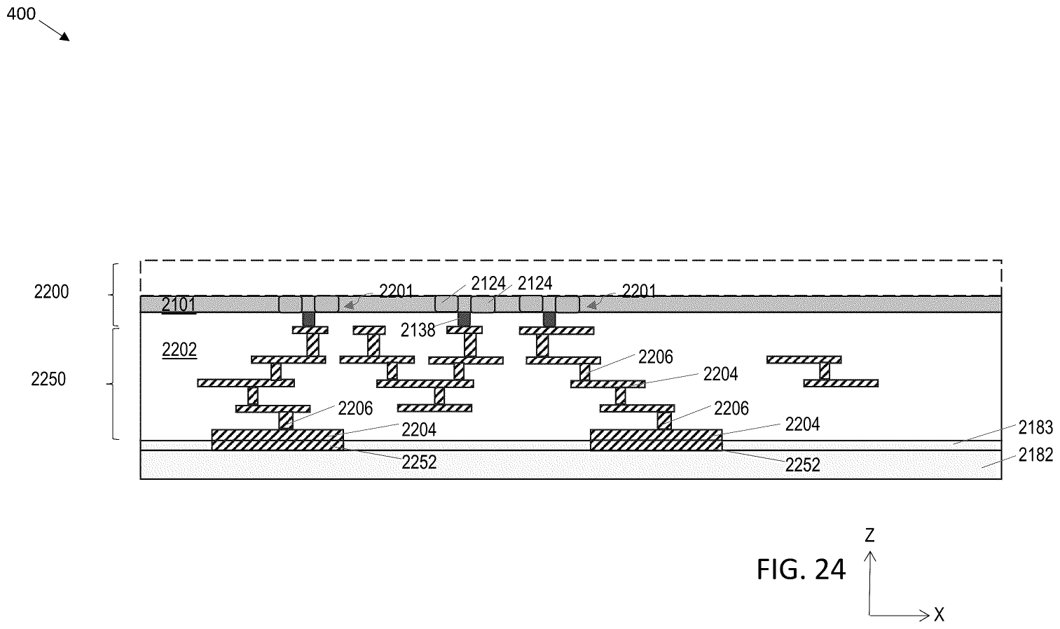

In FIG. 24, a thinning process may be applied to the backside of the substrate 2101. The thinning process may be implemented by using any suitable techniques such as grinding, polishing, and/or chemical etching. For example, a substantial amount of substrate material may be first removed from the backside of the substrate 2101 using a mechanical grinding process. Then, a chemical thinning process may apply an etching chemical to further thin the backside of the substrate 2101. In some embodiments, the thinning process may be performed until a portion of the source/drain regions 2124 is exposed. In some embodiments, the thinning process may be performed until the entire substrate 2101 is removed.

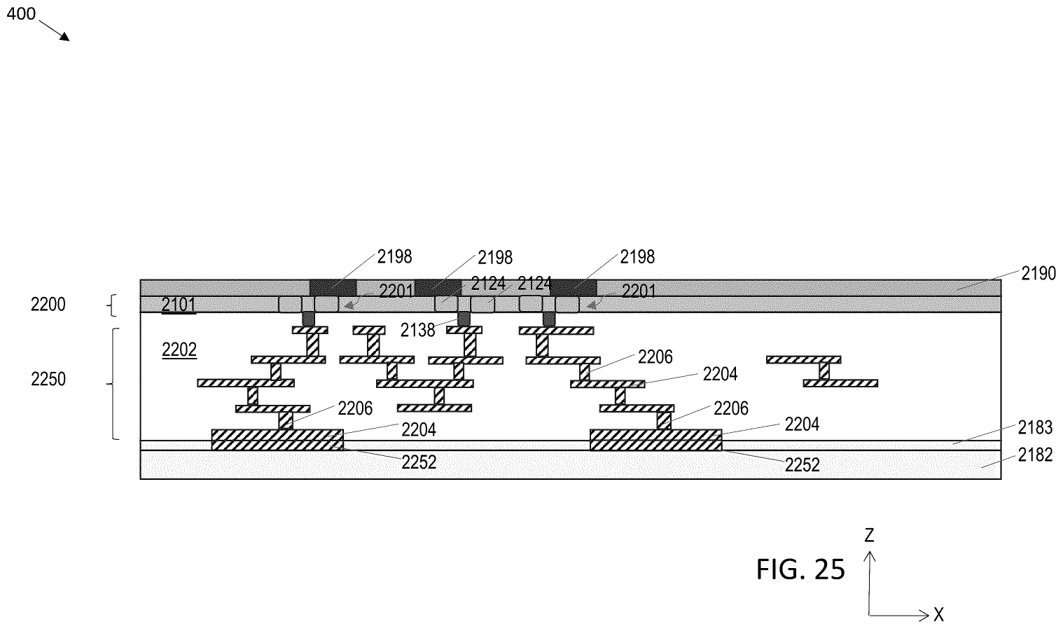

In FIG. 25, a dielectric material layer 2190 is formed over the backside of the substrate 2101, and conducive features 2198 are formed in the dielectric material layer 2190. The conductive features 2198 may be conductive vias for connecting the S/D regions 2124. The dielectric material layer 2190 may be patterned by a photolithography process and one or more etch processes to form openings exposing the source/drain regions 2124 and a portion of the substrate 2101 (if any). After the openings are formed, an electrically conductive material is formed in the openings and over a top surface of the dielectric material layer 2190. Excess portions of the electrically conductive material may be removed from above the top surface of the dielectric material layer 2190 by a planarization process. The planarization process is performed until the dielectric material layer 2190 is revealed, resulting in the conductive features 2198 formed in the dielectric material layer 2190. The dielectric material layer 2190 may include the same material as the IMD layer 2202. The conductive features 2198 may be made of a metal or metal nitride, such as W, Ru, Co, Cu, Ti, TiN, Ta, TaN, Mo, or Ni. The conductive feature 2198 may be formed by any suitable process, such as PVD, electro-plating, or any suitable deposition technique. While not shown, a silicide layer may be selectively formed between the conductive feature 2198 and the S/D regions 2124. In such cases, the silicide layer may include a metal or metal alloy, and the metal includes a noble metal, a refractory metal, a rare earth metal, alloys thereof, or combinations thereof.

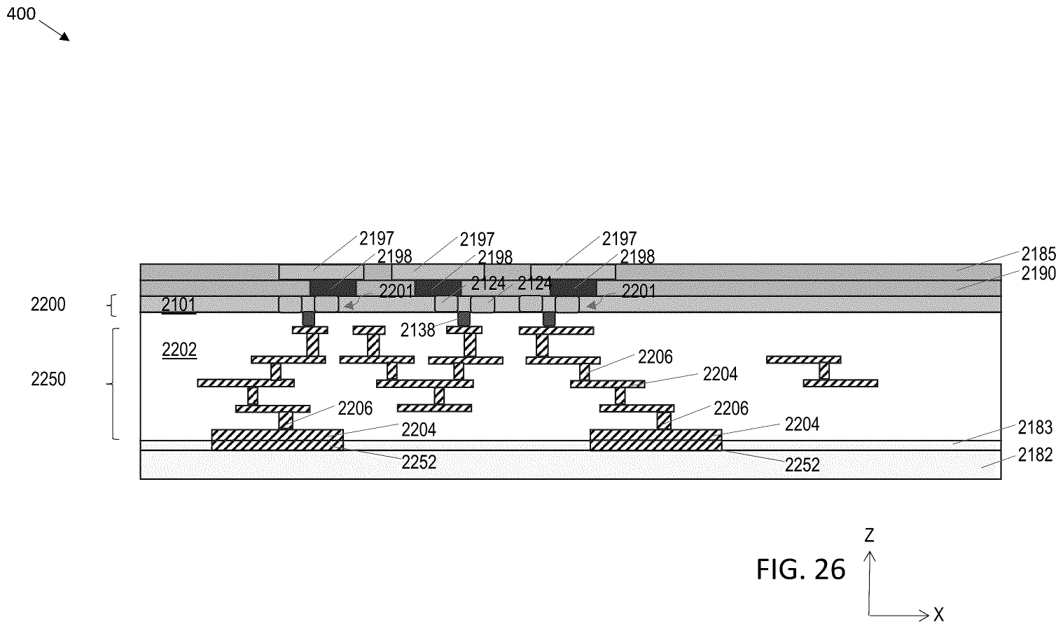

In FIG. 26, after the conductive features 2198 are formed, an ILD layer 2185 is formed on the dielectric material layer 2190 and the conductive features 2198. One or more conductive features 2197 are then formed in the ILD layer 2185. The dielectric material layer 2190 and the ILD layer 2185 may be an interconnect-level layer disposed in the backside interconnect structure. The conductive features 2197 are in electrical communication with the S/D regions 2124 through the conductive feature 2198 and the silicide layer. The conductive features 2197 may serve as a power rail to be connected to a power supply (not shown). In some embodiments, the conductive feature 2197 is a portion of the power rail. In some embodiments, a second ILD layer and second conductive features formed in the second ILD layer may be further provided over the dielectric material layer 2190 and the conductive features 2198. Depending on the layout design, additional ILD layer and conductive features may be formed over the dielectric material layer 2190 and the conductive features 2198 to provide power to various devices in different regions of the semiconductor device structure 400. In such cases, at least one or more conductive features (e.g., conductive features 2197) may be in electrical communication with an array of memory cells in a subsequently formed memory device layer 2194, and at least one or more conductive features (e.g., conductive features 2197) may be in electrical communication with subsequently formed logic devices in a peripheral region. Depending on the conductivity type of the transistor device (e.g., logic device 2201), the power supply connecting to the power rail may be fed with a positive voltage (VDD) or a negative voltage (VSS) (i.e., ground or zero voltage). Having the power supply connected to the conductive features 2197 (e.g., power rail) from the backside of the semiconductor device structure 400 allows for various devices to be powered directly by a backside power, thereby enhancing the device performance, saving an amount of routing resources used on the front side of device, and reducing BEOL process complexity without abnormal electrical mis-connection issues.

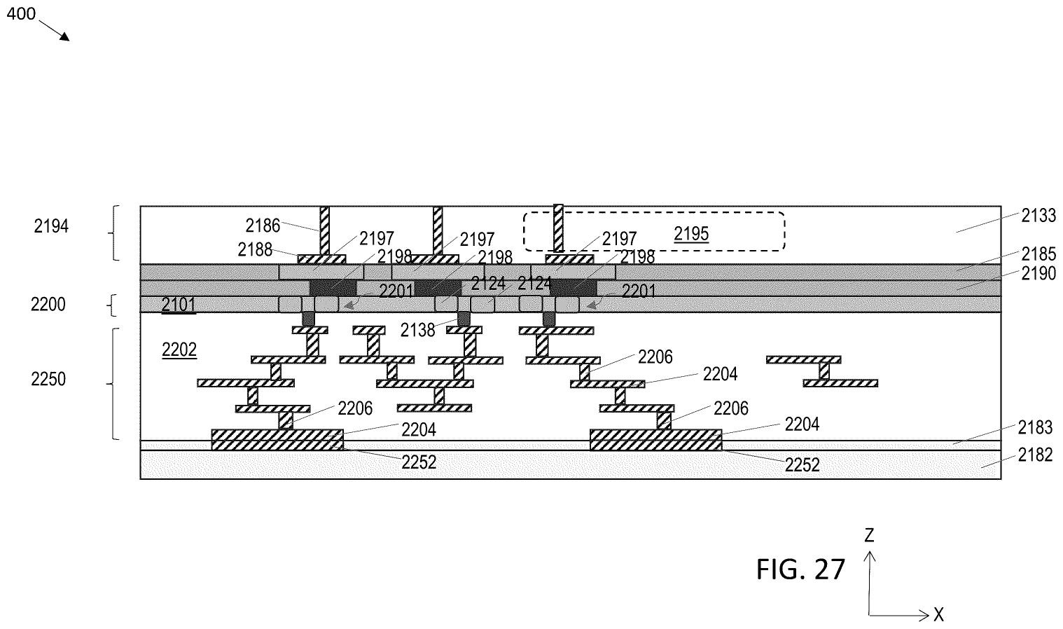

In FIG. 27, a memory device layer 2194 is formed over the ILD layer 2185 and the conductive features 2197. The memory device layer 2194 may include an interconnect dielectric material layer 2133, an array 2195 of non-volatile memory cells formed in the interconnect dielectric material layer 2133, and conductive features 2186, 2188. The conductive features 2186 may be conductive vias, and the conductive features 2188 may be conductive lines. In some embodiments, the memory device layer 2194 (or interconnect dielectric material layer 2133) may be configured to be one of the interconnect-level dielectric layers. In some embodiments, the conductive features 2186, 2188 may be replaced by through hole structures such as through-oxide-via (TOV), through-insulator-via (TIV), or the like. The array 2195 of non-volatile memory cells may include a plurality of 1T FeRAM circuit, such as the GAA device structure 180 shown in FIG. 17, or a plurality of semiconductor device structures 300 shown in FIG. 20. The memory device layer 2194 may be formed in a similar fashion as discussed above with respective to FIGS. 5 to 17. Other non-volatile memory devices, such as resistive random-access memory (RRAM or ReRAM), magneto-resistive random-access memory (MRAM), or phase-change memory (PCM), etc., are contemplated.

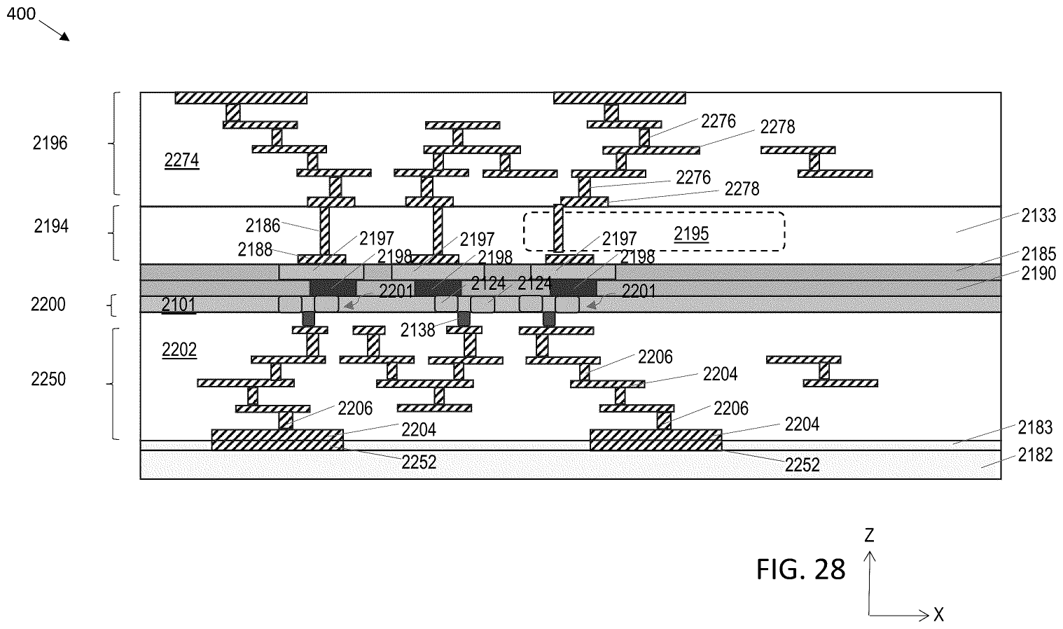

In FIG. 28, a backside interconnect structure 2196, similar to the front side interconnect structure 2250, is formed on the memory device layer 2194. The backside interconnect structure 2196 includes a plurality of intermetal dielectric layers 2274 and conductive features 2276, 2278 formed in each intermetal dielectric layer 2274. The backside interconnect structure 2196 may be configured to provide power supply and/or additional signal connection to various devices in the memory device layer 2194 and the device layer 2200. In some embodiments, the backside interconnect structure 2196 and the front side interconnect structure 2250 may share the same power supply.

As such, the array 2195 of non-volatile memory cells is embedded in the backside interconnect structure 2196 which is disposed away from the device layer 2200. This allows more routing space for the front side of device layer 2200, and the fact that various devices can be powered directly by a backside power saves routing resources used on the front side of device and reduces front side BEOL process complexity without abnormal electrical mis-connection issues. Therefore, the device performance is improved.

Various manufacturing processes may be further performed on the semiconductor device structure 400. For example, after formation of the backside interconnect structure 2196, a redistribution layer (not shown), which may include one or more contact pads formed in one or more passivation layers, may be provided on the backside interconnect structures 2196. The redistribution layer rearranges the wire routing for flip chip bonding or other suitable packaging technology, thereby integrating the semiconductor device structure 400 to a board (e.g., a printed circuit board).

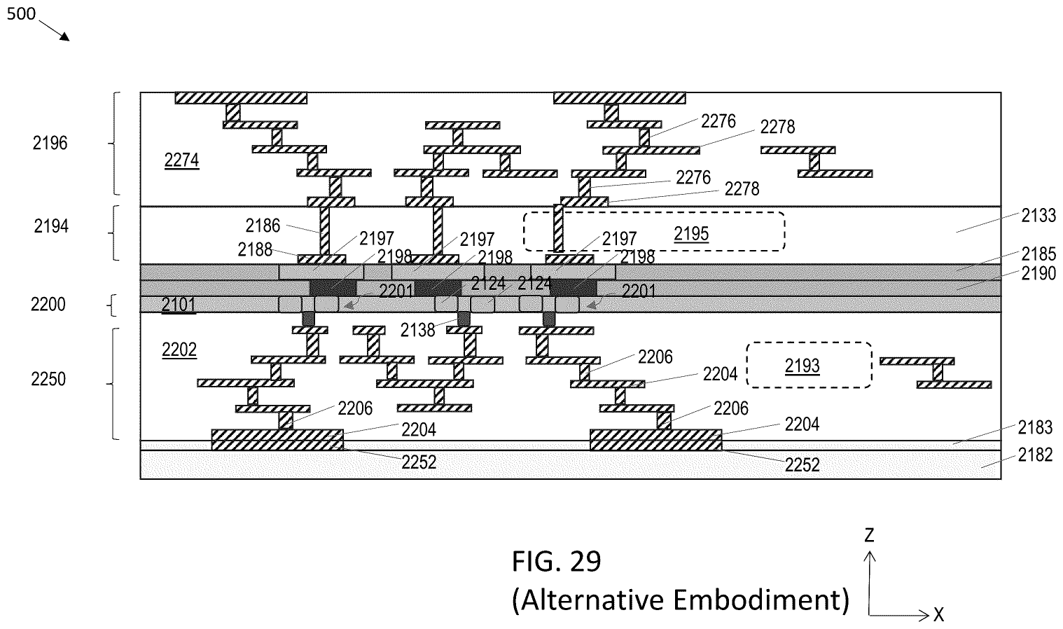

FIG. 29 illustrates a cross-sectional side view of an exemplary semiconductor device structure 500, in accordance with some embodiments of the present disclosure. The semiconductor device structure 500 is substantially identical to the semiconductor device structure 400 except that an array 2193 of non-volatile memory cells is further provided in the front side interconnect structure 2250. Likewise, the array 2193 of non-volatile memory cells may include a plurality of 1T FeRAM circuit, such as the GAA device structure 180 shown in FIG. 17, or a plurality of semiconductor device structures 300 shown in FIG. 20. The array 2193 of non-volatile memory cells may be formed in a similar fashion as discussed above with respective to FIGS. 5 to 17. The array 2193 of non-volatile memory cells and the array 2195 of non-volatile memory cells may be the same, and may be chosen from various non-volatile memory devices, such as ferroelectric random-access memory (FeRAM), resistive random-access memory (RRAM or ReRAM), magneto-resistive random-access memory (MRAM), and phase-change memory (PCM), etc. In some embodiments, the array 2193 of non-volatile memory cells are vertical type GAA structure and the array 2195 of non-volatile memory cells are non-vertical type GAA structure. In some embodiments, the array 2193 of non-volatile memory cells are non-vertical type GAA structures and the array 2195 of non-volatile memory cells are vertical type GAA structures. In some embodiments, the array 2193 of non-volatile memory cells may employs memory devices that are different than memory devices used by the array 2195 of non-volatile memory cells.

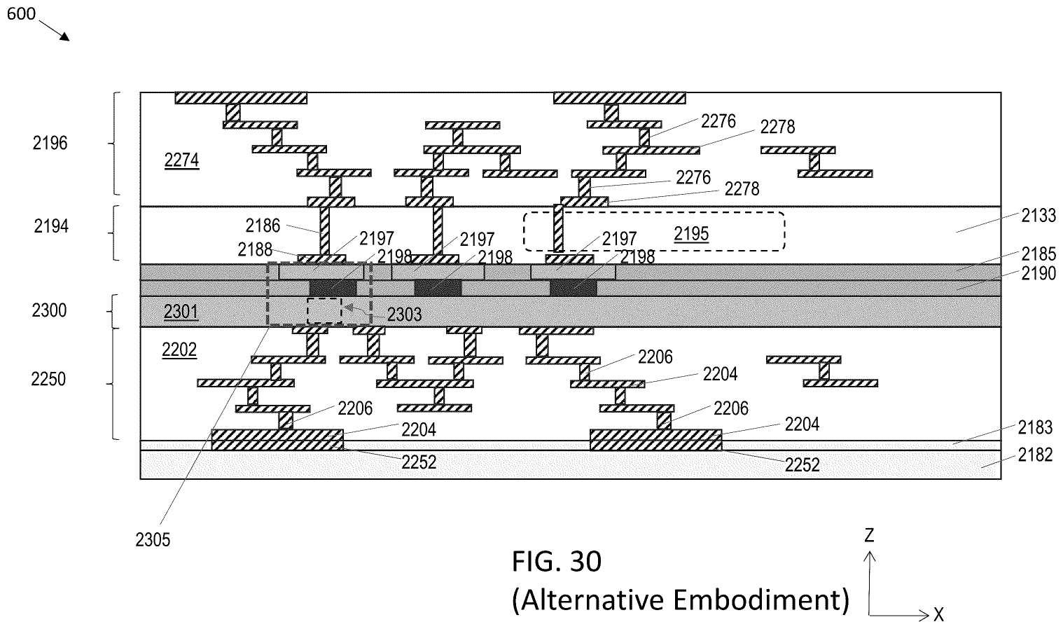

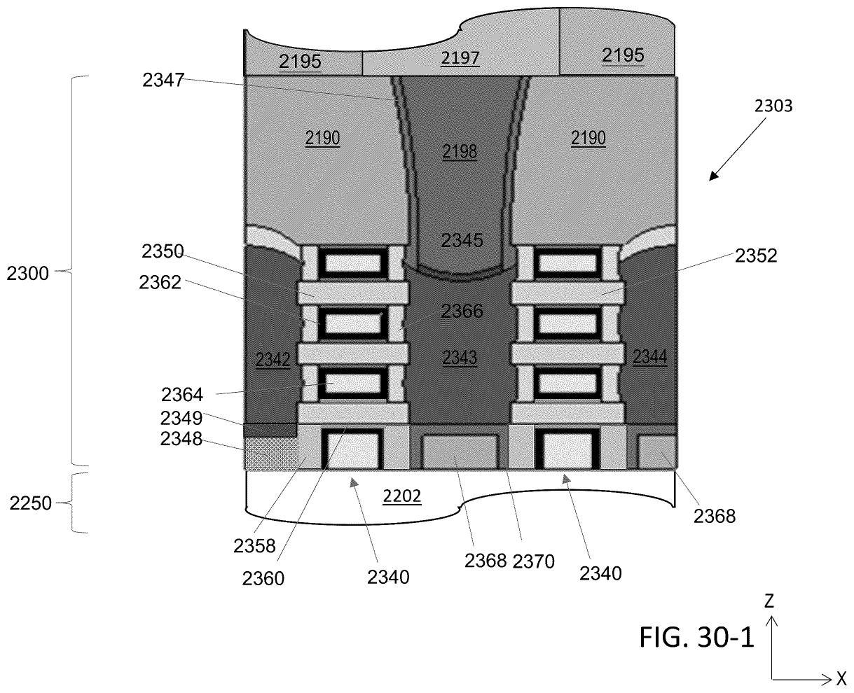

FIG. 30 illustrates a cross-sectional side view of an exemplary semiconductor device structure 600, in accordance with some embodiments of the present disclosure. The semiconductor device structure 600 is substantially identical to the semiconductor device structure 400 except that the device layer 2200 is being replaced with a device layer 2300. FIG. 30-1 illustrates an enlarged view of a portion 2305 of the semiconductor device structure 600 shown in FIG. 30 according to some embodiments of the present disclosure. In FIG. 30-1, the device layer 2300 generally includes a substrate 2301 and one or more nanostructure transistors 2303 disposed in the substrate 2301. The term “nanostructure” is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure transistors may be referred to as nanowire/nanosheet transistors, gate-all-around (GAA) transistors, multi-bridge channel (MBC) transistors, or any transistors having a gate electrode layer surrounding channel regions.

In cases where nanostructure transistor 2303 is a GAA transistor, the nanostructure transistor 2303 may include a gate structures 2340 and epitaxial source/drain (S/D) features 2342, 2343, 2344 disposed on opposite sides of the gate structure 2340. A first and second stacks of semiconductor layers 2350, 2352, which define channel regions for the nanostructure transistor, are disposed between and in contact with the epitaxial S/D features 2342, 2343, 2344, respectively. The gate structures 2340 each includes gate spacers 2358 formed on sidewalls of the gate structures 2340, an interfacial layer (IL) 2360 formed around surfaces of each semiconductor layer of the stack of semiconductor layers 2350, 2352, a high-k (HK) dielectric layer 2362 formed around each semiconductor layer of the stack of semiconductor layers 2350, 2352, and a gate electrode layer 2364 formed on the HK dielectric layer 2362 surrounding each semiconductor layer of the stack of semiconductor layers 2350, 2352. An inner spacer 2366 is formed between the gate electrode layer 364 and the epitaxial S/D features 2342, 2343, 2344.

S/D contact 2348 is disposed on a first side (e.g., front side) of the device layer 2300. The S/D contact 2348 is separated from the epitaxial S/D feature 2342 by a silicide layer 2349. The silicide layer 2349 may be made of a metal or metal alloy. An interlayer dielectric (ILD) layer 2368 is disposed on the first side of device layer 2300 and separated from the epitaxial S/D features 2343, 2344 by a contact etch stop layer (CESL) 2370. Surfaces of portions of the S/D contact 2348, the gate spacers 2358, the HK dielectric layer 2362, the gate electrode layer 2364, the ILD layer 2368, and the CESL 2370 are substantially co-planar and in contact with the front side interconnect structure 2202.

The front side interconnect structure 2202 may include a plurality of conductive lines 2204 and conductive vias 2206 formed in an IMD layer 2202, as shown in FIG. 30. The conductive features (e.g., backside power rail) 2198 is formed on a second side (e.g., backside) of the device layer 2300 opposing the first side. The conductive features 2198 may be formed after the front side interconnect structure 2250 has been formed on the first side. In some embodiments, after the carrier substrate 2182 is temporarily attached to the front side interconnect structure 2250 and the carrier substrate 2182 is flipped over, a thinning process is performed to remove portions of the substrate 2301. Next, a hard mask (not shown) may be formed on a portion of the substate 2301 over the epitaxial S/D features (e.g., epitaxial S/D feature 2343) to be connected to the conductive features (e.g., backside power rail) 2198. The portion of the substrate 2301 not covered by the hard mask is then removed to form an opening exposing epitaxial source/drain (S/D) features (e.g., epitaxial S/D features 342, 344), which may be an epitaxial drain feature. A liner 2347 is formed on the exposed epitaxial drain features. The liner 2347 may be formed of nitrides or metal nitrides, such as SiN, TaN, TiN, WN, MoN, or the like. A dielectric material 2190, which may be any suitable dielectric material, such as an oxide, is then formed on the liner 2347 and fills the opening. The remaining portion of the substrate 2301 that was not covered by the hard mask is then removed to form an opening exposing epitaxial S/D features (e.g., epitaxial S/D feature 2343) that was previously protected by the hard mask, resulting in a plurality of epitaxial source features (e.g., epitaxial S/D feature 2343) exposed through the openings, while a plurality of epitaxial drain features (e.g., epitaxial S/D feature 2342, 2344) disposed below the dielectric material 2372.

Backside silicide layers 2345, which may be made of a metal or metal alloy, is selectively formed on the exposed epitaxial source features (e.g., epitaxial S/D feature 2343). An electrically conductive feature is then formed in the opening on the silicide layer 2345, forming the conductive features (e.g., backside power rail) 2198 for the device layer 2300. After the conductive features (e.g., backside power rail) 2198 are formed, a planarization process (e.g., CMP) is performed on the backside of the device layer 2300 so that exposed surfaces of the conductive features 2198, the liner 2347, and the dielectric material 2190 are substantially co-planar. After CMP, an ILD layer 2185 is formed on the dielectric material layer 2190 and the conductive features 2198. One or more conductive features 2197 are then formed in the ILD layer 2185.

As such, the epitaxial source features (e.g., epitaxial S/D feature 2343) are connected to the conductive features (e.g., backside power rail) 2198 disposed on the backside of the device layer 2300, which can be powered directly by a positive voltage (VDD) or a negative voltage (VSS) (i.e., ground or zero voltage), while the epitaxial drain features (e.g., epitaxial S/D feature 2342, 2344) are connected to a power rail (not shown) disposed on the front side of the device layer 2300. The use of the backside power rail (e.g., conductive features 2198) saves an amount of routing resources used on the front side of device layer 2300, and reduces BEOL process complexity without abnormal electrical mis-connection issues. In addition, power consumption of the semiconductor device structure 600 and the memory device layer 2194 to be formed on the device layer 2300 can be lowered since the power can be provided through both the backside and front side of the device layer 2300.

Various embodiments of the present disclosure are directed to semiconductor device structures having an array of memory cell devices disposed in a Back-End-Of-Line (BEOL) structure to improve device density and performance. Each memory cell device may be a vertical-type gate-all-around (GAA) device structure in which a channel region is surrounded by a layer of ferroelectric material (e.g., FeRAM memory cell). The vertical-type GAA device structure provides a large effective area for the capacitor or memory device and increased charge storage capability. In addition, since the array of memory cell devices are disposed between BEOL metal routings in the interconnect structure that is away from the front-end transistor devices, additional space can be provided for complicated front-end transistor devices, thereby improving the performance of the overall structure. In some embodiments, the array of memory cell devices is disposed between a backside power rail and a backside interconnect structure for increased charge storage capability while providing increased routing space for the front side of device layer.

An embodiment is a semiconductor device structure. The semiconductor device structure includes a device layer having a first side and a second side opposing the first side, and a first interconnect structure disposed over the first side of the device layer. The first interconnect structure includes a first interconnect-level layer, a second interconnect-level layer disposed over the first interconnect-level layer, wherein the second interconnect-level layer comprises an array of vertical-type memory cell devices. The semiconductor device structure also includes a third interconnect-level layer disposed over the second interconnect-level layer.

Another embodiment is a semiconductor device structure. The semiconductor device structure includes a device layer having a first side and a second side opposing the first side, a first interconnect structure disposed adjacent the first side of the device layer, and a memory device layer disposed over the second side of the device layer. The memory device layer includes a first set of memory cell devices arranged in a first column extending a first direction, wherein each memory cell device has a vertically disposed channel region being surrounded by a first ferroelectric material layer. The memory device layer also includes a bit line coupled to the first set of memory cell devices and extending along the first direction. The semiconductor device structure also includes a second interconnect structure disposed over the memory device layer.

A further embodiment is a method for forming a semiconductor device structure. The method includes providing a first interconnect structure over a first side of a device layer, wherein the device layer has a substrate comprising one or more logic devices, attaching the first interconnect structure to a carrier substrate, flipping the carrier substrate such that a second side of the device layer is facing up to expose a backside of the substrate, removing a portion of the substrate from the backside, forming a dielectric material layer over the backside of the substrate, wherein the dielectric material layer comprises a power rail coupling to a power supply. The method also includes forming a memory device layer over the dielectric material layer, wherein the memory device layer comprises an array of vertical-type memory cell devices. The method further includes providing a second interconnect structure over the memory device layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a device layer having a first side and a second side opposing the first side;
a first interconnect structure disposed over the first side of the device layer, the first interconnect structure comprising:
a first interconnect-level layer;
a second interconnect-level layer disposed over the first interconnect-level layer, wherein the second interconnect-level layer comprises an array of vertical-type memory cell devices; and
a third interconnect-level layer disposed over the second interconnect-level layer.

2. The semiconductor device structure of claim 1, wherein each memory cell device is electrically connected to a bit line and is surrounded by a word line, and the bit line extends along a first direction that is perpendicular or non-perpendicular to a second direction of the word line.

3. The semiconductor device structure of claim 1, wherein each memory cell device is a ferroelectric random-access memory (FeRAM), a resistive random-access memory (RRAM or ReRAM), a magneto-resistive random-access memory (MRAM), or a phase-change memory (PCM).

4. The semiconductor device structure of claim 1, wherein each memory cell device is a gate-all-around (GAA) structure having a channel region surrounded by a ferroelectric material layer, and the channel is vertically disposed between a top source/drain feature and a bottom source/drain feature.

5. The semiconductor device structure of claim 4, wherein the array of memory cell devices comprises at least two GAA structures stacked vertically.

6. The semiconductor device structure of claim 4, wherein each memory cell device is a one-transistor (1T) FeRAM device.

7. The semiconductor device structure of claim 4, wherein the channel region comprises InGaZnO (IGZO) and the ferroelectric material layer comprises hafnium zirconium oxide (HZO).

8. The semiconductor device structure of claim 1, wherein the device layer comprises one or more logic devices, and each logic device is a planar field effect transistor (FET), a three-dimensional fin-like FET (FinFET), a gate-all-around (GAA) FET, a forksheet FET, or a complementary FET (CFET).

9. The semiconductor device structure of claim 1, further comprising:
a second interconnect structure disposed over the second side of the device layer.

10. The semiconductor device structure of claim 9, wherein the second interconnect structure comprises an array of memory cell devices.

11. A semiconductor device structure, comprising:
a device layer having a first side and a second side opposing the first side;
a first interconnect structure disposed adjacent the first side of the device layer;
a memory device layer disposed over the second side of the device layer, the memory device layer comprising:
a first set of memory cell devices arranged in a first column extending a first direction, wherein each memory cell device has a vertically disposed channel region being surrounded by a first ferroelectric material layer; and
a bit line coupled to the first set of memory cell devices and extending along the first direction; and
a second interconnect structure disposed over the memory device layer.

12. The semiconductor device structure of claim 11, further comprising:
a dielectric material layer disposed over the memory device layer, the dielectric material layer comprises a power rail operable to electrically connect the device layer to a power supply.

13. The semiconductor device structure of claim 11, further comprising:
a word line arranged to extend along a second direction that is different from the first direction.

14. The semiconductor device structure of claim 13, wherein the first direction is non-perpendicular to the second direction.

15. The semiconductor device structure of claim 13, wherein the word line is extended to surround each memory cell device.

16. The semiconductor device structure of claim 11, further comprising:
a second set of memory cell devices arranged in a first column extending a first direction, wherein each memory cell device of the second set of memory cell devices has a vertically disposed channel region being surrounded by a second ferroelectric material layer, and wherein at least a memory cell device of the first set of memory cell devices and at least a memory cell device of the second set of memory cell devices are vertically stacked and connected to one other.

17. The semiconductor device structure of claim 16, wherein the channel region comprises InGaZnO (IGZO) and the first ferroelectric material layer comprises hafnium zirconium oxide (HZO).

18. The semiconductor device structure of claim 16, wherein each memory cell device of the first and second sets of memory cell devices is a one-transistor (1T) FeRAM device.

19. A method for forming a semiconductor device structure, comprising:
providing a first interconnect structure over a first side of a device layer, wherein the device layer has a substrate comprising one or more logic devices;
attaching the first interconnect structure to a carrier substrate;
flipping the carrier substrate such that a second side of the device layer is facing up to expose a backside of the substrate;
removing a portion of the substrate from the backside;
forming a dielectric material layer over the backside of the substrate, wherein the dielectric material layer comprises a power rail coupling to a power supply;
forming a memory device layer over the dielectric material layer, wherein the memory device layer comprises an array of vertical-type memory cell devices; and
providing a second interconnect structure over the memory device layer.

20. The method of claim 19, wherein device layer comprises one or more logic devices, and each logic device is a planar field effect transistor (FET), a three-dimensional fin-like FET (FinFET), a gate-all-around (GAA) FET, a forksheet FET, or a complementary FET (CFET).
